(19) United States
(12) Patent Application Publication
(10) Pub. No.: US 2015/0048452 A1
(43) Pub. Date: Feb. 19, 2015

(54) ULTRA-HIGH VOLTAGE SEMICONDUCTOR HAVING AN ISOLATED STRUCTURE FOR HIGH SIDE OPERATION AND METHOD OF MANUFACTURE

(71) Applicant: Macronix International Co., Ltd., Hsinchu (TW)

(72) Inventors: Chieh-Chih Chen, Hsinchu County (TW); Yu-Jui Chang, Hsinchu City (TW); Cheng-Chi Lin, Yilan County (TW); Shih-Chin Lien, Taipei County (TW); Shyi-Yuan Wu, Hsinchu City (TW)

(73) Assignee: Macronix International Co., Ltd., Hsinchu (TW)

(21) Appl. No.: 13/968,986

(22) Filed: Aug. 16, 2013

(51) Int. Cl. H01L 29/78; H01L 29/66

(52) U.S. Cl. CPC H01L 29/7823; H01L 29/66681
USPC 257/343; 438/286

(57) ABSTRACT

A semiconductor device, in particular, an ultra-high metal oxide semiconductor (UHV MOS) device, is defined by a doped gradient structure in a drain region. For example, an ultra-high n-type metal oxide semiconductor (UHV NMOS) device is defined by an n-doped gradient structure in the drain region. The n-doped gradient structure has at least one of a high voltage n- (HVN-) well, a drain side high voltage n-type deep (HVND) well, and a drain side n-type well (NW) disposed in the drain region. A drain side n+ well is additionally disposed in the at least one of the HVN- well, the drain side HVND well, and the drain side NW. A method of manufacturing a UHV NMOS device having a doped gradient structure of a drain region is also provided.

### TECHNOLOGICAL FIELD

The present invention generally relates to a semiconductor device having a substantially improved resilience of breakdown voltage after repeated use. In particular, the present invention relates to an ultra-high voltage metal oxide semiconductor having a modified double diffusion drain structure. The present invention is also directed to a method for fabricating such semiconductor devices.

### BACKGROUND

Advancements in the manufacture of semiconductor devices continue to emphasize the miniaturization of MOS transistors. High voltage metal oxide semiconductor HVMOS transistor designs tend to limit the extent of reduction in size of the transistor. Thus a semiconductor device using HVMOS transistors is limited in the number of integrated circuits that can be fabricated on a wafer.

Ultra-high voltage metal oxide semiconductor (UHV MOS) devices attempt to integrate ultra-high voltage device structures with lower voltage device structures. For example, ultra-high voltage devices may include a laterally diffused metal oxide semiconductor and a double diffused drain metal oxide semiconductor.

Laterally diffused metal oxide semiconductor (LDMOS) transistor structures are characterized by higher junction breakdown voltages, but generally require larger sizes. The LDMOS transistor is characterized by a lateral-diffused drift region having a low dopant concentration but a relatively large area, which in part lends to the larger size of the device. The drift region of the LDMOS is used to alleviate the high voltage between the drain and the source allowing for an increased breakdown voltage. LDMOS transistors have adopted smaller gate structures to reduce their size and to improve their reliability in high-speed operations, but this also leads to a short channel effect and a reduction in the threshold voltage.

The structure of a lightly doped drain metal oxide semiconductor (LDD MOS) attempts to inhibit the short channel effect resulting in a reduced channel electric field by lowering the density of doping at the drain and source regions. Lower density doping in these regions, reduces the applied voltage, which results in a reduction in the intensity of the electric field needed to be induced across the source and drain regions. A disadvantage of LDD MOS devices is an increase in the number of photoresist steps that are normally required for conventional MOS devices.

A common problem in conventional UHV MOS devices is the difficulty in reliable improvement in breakdown voltages. For example, the UHV MOS may operate in a voltage range of 0 to 600 V. The breakdown voltage of the entire circuit not only depends upon the breakdown voltage of the UHV MOS devices, but also depends upon the impact on breakdown voltage of the interconnection structures for conducting the high voltages in the circuit.

Double diffused drain metal oxide semiconductor (DDD MOS) devices are suitable for use as high voltage transistors (i.e., HVMOS transistors). However, conventional DDD MOS devices have not been effective at undergoing a severe reliability test. For example, the high temperature reverse bias (HTRB) test is a commonly used severe reliability test. The high dosage of dopants at the drain region tend to lead to gate induced drain leakage as a result of the high electric field that is induced between the gate electrode, which may be relatively close to ground, and the drain where the high voltage is applied. Gate induced drain leakage requires a reduction in the specification of the threshold voltage of the device.

Additionally, the continued use of conventional UHV MOS transistors tends to exhibit degradation in the breakdown voltage of the device over time. There remains a need in the art for HVMOS transistor structures having greater operating resilience but without substantially increasing the number of processing steps needed to fabricate the device.

### BRIEF SUMMARY OF EXEMPLARY EMBODIMENTS

Embodiments of semiconductor devices of the present invention are provided having a more sustainable breakdown voltage over continued use of the device.

An aspect of the invention provides an ultra-high voltage metal oxide semiconductor (UHV MOS) device comprising a MOS transistor having a doped gradient structure in a drain region; a high voltage (HV) interconnection region proximate to the MOS transistor, the HV interconnection region having at least one dielectric layer and at least one metal layer; a self-shielding region proximate to the MOS transistor and aligned with the HV interconnection region; and a high side operating region (HSOR) separated from the MOS transistor by the HV interconnection region and the self-shielding region.

In an embodiment of the invention, the UHV MOS device the doped gradient structure may comprise at least one of a high voltage n- (HVN-) well, a high voltage n-type deep (HVND) well, and an n-type well (NW). In certain embodiments of the invention, the doped gradient structure may additionally comprise an n+ well.

Certain embodiments of the invention also includes an ultra-high voltage n-type metal oxide semiconductor (UHV NMOS) device in particular comprising a substrate having an epitaxial layer disposed in part therein and a drain region having an n-doped gradient structure and a first n-type buried layer (NBL) at a terminus of the drain region.

In certain embodiments of the invention, the epitaxial layer of the UHV NMOS device may be at least one of a p-type epitaxial (p-epi) layer or an n-type epitaxial (n-epi) layer. In certain embodiments of the invention, the n-doped gradient structure comprises at least one of a high voltage n- (HVN-) well, a high voltage n-type deep (HVND) well, and an n-type well (NW). In certain embodiments of the invention, the n-doped gradient structure additionally comprises an n+ well.

In an embodiment of the invention, the UHV NMOS device may additionally comprise a bulk region and a source region diametrically opposed to the drain region, the bulk region and the source region defined by a second NBL disposed in part in the substrate and another part in the epitaxial layer, a first high voltage p-type deep (HVPD) well disposed in part in the second NBL and a remaining part above the second NBL, a bulk p+ well disposed in the first HVPD well to define a bulk contact, and a source n+ well disposed in the first HVPD well to define a source contact; a channel region separating the drain region from the bulk region and the source region, the channel region having a first high voltage n well (HVNW) extending from the bulk region and the source region across the channel region to the drain region; and a gate region proximate to the bulk region and the source region and aligned in part above the channel region, the gate region having a conductive layer. In certain embodiments of the invention, the second NBL underlies the bulk p+ well and the source n+ well of the bulk region and the source region.

In certain embodiments of the invention, the channel region of the UHV NMOS device may additionally comprise a p top region disposed along a shielded top surface of the substrate. In certain other embodiments of the invention, the p top region may comprise a plurality of discrete p top segments.

In an embodiment of the invention, the UHV NMOS device may additionally comprise a self-shielding region aligned with the terminus of the drain region opposite a side of the drain region aligned with the channel region, the self-shielding region having a second HVPD well; a high voltage (HV) interconnection region aligned above the self-shielding region having at least one dielectric layer, and at least one metal layer; and a high side operating region (HSOR) separated from the drain region by the HV interconnection region and the self-shielding region having at least a part of a third NBL that extends across the HSOR, a second HVNW extending substantially across the HSOR and disposed in part in the third NBL and another remaining part above the third NBL, an n well (NW) disposed proximate to the self-shielding region, a p well (PW) disposed diametrically opposed to the NW at an opposite side of the HSOR, a first HSOR n+ well disposed in the NW, a HSOR p+ well disposed in the PW, and a second HSOR n+ well disposed in the PW. In certain embodiments of the invention, the second HVPD well of the UHV NMOS device may comprise two or more discrete HVPD well segments.

In an embodiment of the invention, the at least one dielectric layer may comprise an interlayer dielectric (ILD) layer disposed on the substrate and an inter-metal dielectric (IMD) layer, and the at least one metal layer may comprise a first metal disposed on the ILD layer and a second metal layer separated from the first metal layer by the IMD layer. In certain embodiments of the invention, the first metal layer is patterned such that only a portion of the second metal layer lies above the self-shielding region. In certain other embodiments of the invention, the second metal is patterned such that only a portion of the first metal layer lies above the self-shielding region. Further pursuant to this embodiment of the invention, the portion of the first metal layer aligned above the self-shielding region is a patterned region of the first metal layer.

In an embodiment of the invention, the UHV NMOS device may additionally comprise a substrate contact region aligned with the bulk region and the source region opposite a side of the bulk region and the source region aligned with the channel region, the substrate contact having a third HVPD well, and a substrate contact p+ well disposed in the third HVPD well; and a patterned isolation layer disposed along the substrate.

In an embodiment of the invention, the UHV NMOS device may further additionally comprises a patterned isolation layer disposed along the substrate. In certain embodiments of the invention, the patterned isolation layer is a field oxide layer. In certain other embodiments of the invention, the patterned isolation layer is one or more shallow trench isolation (STI) structures. In yet certain other embodiments of the invention, the patterned isolation structure may comprise a combination of a field oxide layer and one or more STI structures.

An aspect of the invention provides methods of fabricating a ultra-high voltage n-type metal oxide semiconductor (UHV NMOS) device, the method comprising providing a substrate; implanting an n-type buried layer (NBL) in the substrate; driving in a dopant of the NBL; depositing an epitaxial layer; implanting a high voltage p-type deep (HVPD) well; implanting a high voltage n well (HVNW); implanting an n well (NW) in the high side operating region (HSOR); implanting a p well (PW) in the HSOR; driving in a dopant of the NW; implanting a p top layer; forming an isolation layer; forming a conductive layer; and implanting an n-doped gradient structure in a drain region.

In an embodiment of the invention, the step of implanting the n-doped gradient structure in the drain region may comprise the additional steps of implanting at least one of a high voltage n- (HVN-) well, a drain side high voltage n-type deep (HVND) well, and a drain side n-type well (NW) and implanting a drain side n+ well in at least one of the HVN- well, the drain side HVND well, and the drain side NW.

In certain embodiments of the invention, the method of fabricating the UHV NMOS device additionally comprises implanting a source side n+ well, a first HSOR n+ well, and a second HSOR n+ well and implanting a substrate contact p+ well, a bulk side p+ well, and a HSOR p+ well.

An additional aspect of the invention provides ultra-high voltage metal oxide semiconductor (UHV MOS) devices manufactured according to the methods of the invention.

These embodiments of the invention and other aspects and embodiments of the invention will become apparent upon review of the following description taken in conjunction with the accompanying drawings. The invention, though, is pointed out with particularity by the appended claims.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1A is a top view illustrating an ultra-high voltage (UHV) MOS device according to an embodiment of the invention;

FIG. 1B is a detail view illustrating the UHV MOS device of FIG. 1A;

FIG. 1C is a more detailed view illustrating the UHV MOS device of FIG. 1B;

FIG. 2 is a top view illustrating a conventional UHV MOS device;

FIG. 3A is a cross-sectional view illustrating a conventional ultra-high voltage n-type metal oxide semiconductor (UHV NMOS);

FIG. 3B is a cross-sectional view illustrating an UHV NMOS according to an embodiment of the invention;

FIG. 4A is a top view of a cell of an UHV NMOS device according to an embodiment of the invention;

FIG. 4B is a cross-sectional view illustrating the UHV NMOS device taken along the BB′ line of FIG. 4A;

FIG. 5 is a cross-sectional view illustrating an UHV NMOS device according to an embodiment of the invention being subjected to a high temperature reserve bias (HTRB) reliability test;

FIG. 6A is a graphical representation of the results of a TCAD simulation of an UHV NMOS device according to an embodiment of the invention;

FIG. 6B is a doping profile for the drain region of a UHV NMOS device according to an embodiment of the invention;

FIG. 6C are doping profiles for various types of dopants at the drain region of a UHV NMOS device according to various embodiments of the invention;

FIG. 7A is a cross-sectional view illustrating an UHV NMOS after undergoing certain fabrication steps according to an embodiment of the invention;

FIG. 7B is a cross-sectional view illustrating an UHV NMOS after undergoing certain fabrication steps according to another embodiment of the invention;

FIG. 7C is a cross-sectional view illustrating an UHV NMOS after undergoing certain fabrication steps according to yet another embodiment of the invention;

FIG. 7D is a cross-sectional view illustrating an UHV NMOS after undergoing certain fabrication steps according to even yet another embodiment of the invention;

FIG. 8 is a process flow diagram showing the various steps of fabricating an UHV NMOS device according to an embodiment of the invention;

FIG. 9 is a cross-sectional view illustrating an UHV NMOS according to another embodiment of the invention;

FIG. 10 is a cross-sectional view illustrating an UHV NMOS according to another embodiment of the invention;

FIG. 11 is a cross-sectional view illustrating an UHV NMOS according to another embodiment of the invention;

FIG. 12 is a cross-sectional view illustrating an UHV NMOS according to another embodiment of the invention;

FIG. 13 is a cross-sectional view illustrating an UHV NMOS according to another embodiment of the invention;

FIG. 14 is a cross-sectional view illustrating an UHV NMOS according to another embodiment of the invention;

FIG. 15 is a cross-sectional view illustrating an UHV NMOS according to another embodiment of the invention;

FIG. 16 is a cross-sectional view illustrating an UHV NMOS according to another embodiment of the invention;

FIG. 17 is a cross-sectional view illustrating an UHV NMOS according to another embodiment of the invention;

FIG. 18 is a cross-sectional view illustrating an UHV NMOS according to another embodiment of the invention;

FIG. 19 is a cross-sectional view illustrating an UHV NMOS according to another embodiment of the invention;

FIG. 20 is a cross-sectional view illustrating an UHV NMOS according to another embodiment of the invention;

FIG. 21 is a cross-sectional view illustrating an UHV NMOS according to another embodiment of the invention;

FIG. 22 is a cross-sectional view illustrating an UHV NMOS according to another embodiment of the invention;

FIG. 23 is a cross-sectional view illustrating an UHV NMOS according to another embodiment of the invention;

FIG. 24 is a cross-sectional view illustrating an UHV NMOS according to another embodiment of the invention;

FIG. 25 is a cross-sectional view illustrating an UHV NMOS according to another embodiment of the invention;

FIG. 26 is a cross-sectional view illustrating an UHV NMOS according to another embodiment of the invention;

FIG. 27 is a cross-sectional view illustrating an UHV NMOS according to another embodiment of the invention;

FIG. 28 is a cross-sectional view illustrating an UHV NMOS according to another embodiment of the invention;

FIG. 29 is a cross-sectional view illustrating an UHV NMOS according to another embodiment of the invention;

FIG. 30A is a top view illustrating a single UHV cell of a semiconductor device according to an embodiment of the invention;

FIG. 30B is a top view illustrating multiple UHV cells of a semiconductor device according to an embodiment of the invention; and

FIG. 31 is a cross-sectional view illustrating an UHV NMOS according to another embodiment of the invention.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

As used in the specification and in the appended claims, the singular forms “a”, “an”, and “the” include plural referents unless the context clearly indicates otherwise. For example, reference to “a MOS device” includes a plurality of such MOS devices.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

The inventors have conceived of a semiconductor device, in particular, an ultra-high voltage metal oxide semiconductor device (UHV MOS) having improved resilience of response even as the device is used over time. The inventors have conceived of a design of a device having improved reliability but lacking any substantial increase in device area in comparison to conventional devices.

A UHV MOS of the invention, in certain embodiments, is defined by a metal oxide semiconductor transistor, a high voltage (HV) interconnection region proximate to the MOS transistor, a self-shielding region aligned with the HV interconnection region, and a high side operating region (HSOR) separated from the MOS transistor by the HV interconnection region and the self-shielding region.

According to an embodiment of the invention, a drain region of the UHV MOS device of the invention comprises a double diffused drain (DDD)-type configuration. In certain embodiments, the DDD-type configuration of the invention differs substantially from a conventional DDD-type structure. As such, as further defined herein, a drain region of the UHV MOS device of the invention comprises a doped gradient structure.

According to an embodiment of the invention, a drain region of an ultra-high voltage n-type metal oxide semiconductor (UHV NMOS) device of the invention may comprise an n-doped gradient structure. According to another embodiment of the invention, a drain region of an ultra-high voltage p-type metal oxide semiconductor (UHV PMOS) device of the invention may comprise a p-doped gradient structure.

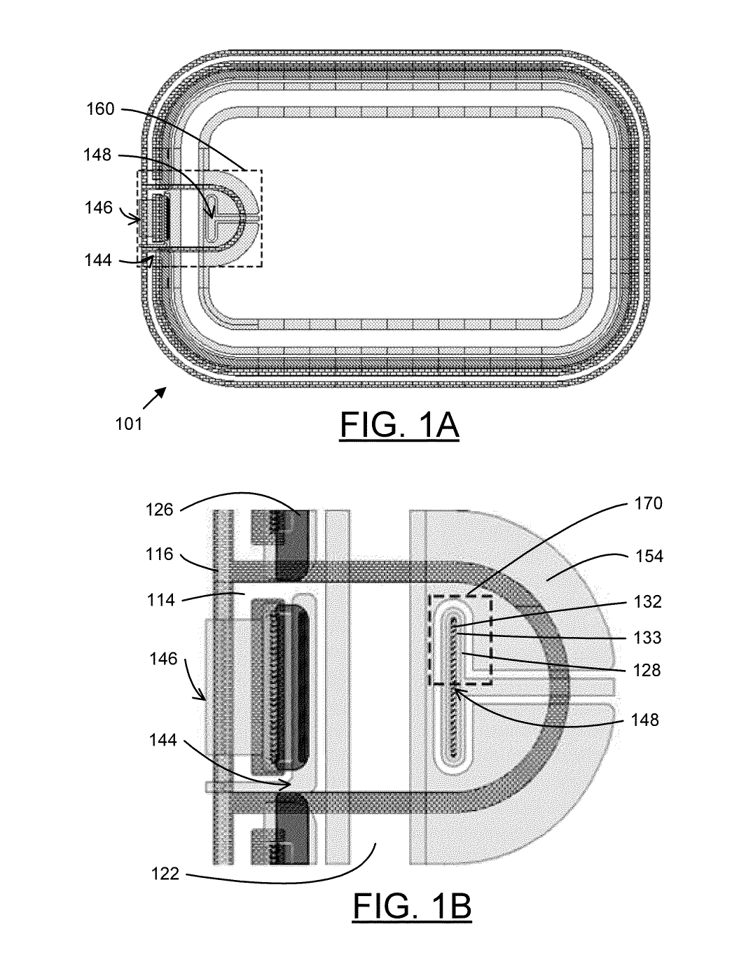

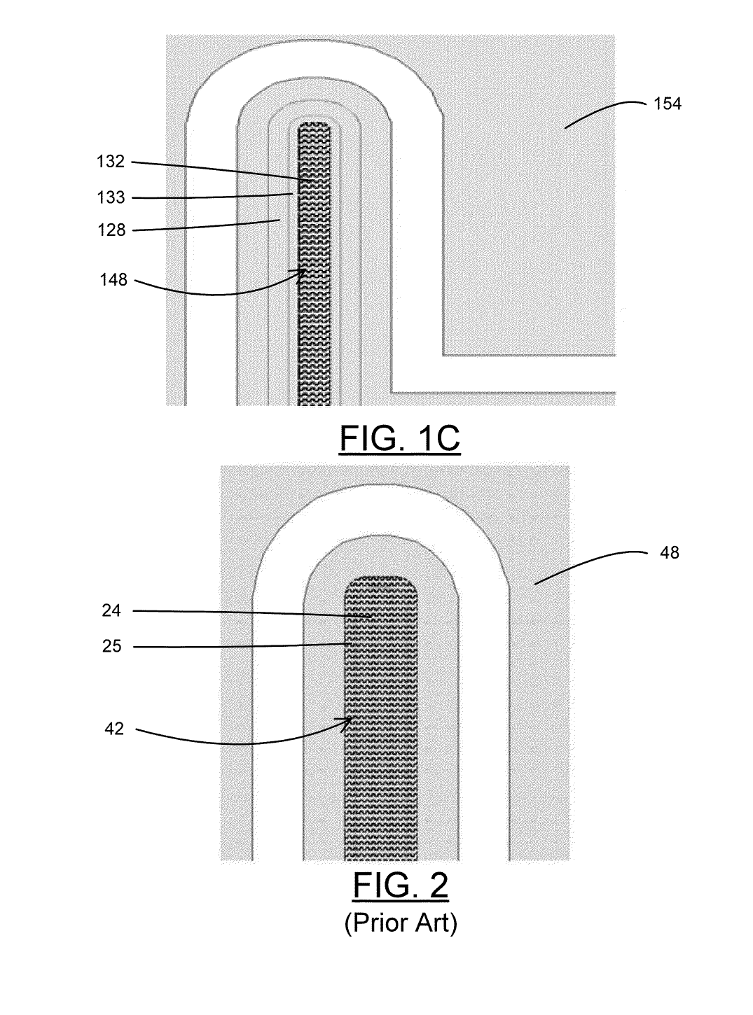

FIG. 1A is a top view illustrating an ultra-high voltage metal oxide semiconductor (UHV MOS) device according to an exemplary embodiment of the invention. The UHV MOS 101 of FIG. 1A showing, inter alia, a gate region 144, a bulk and source region 146, and a drain region 148 of the device, the bulk and source region 146 collectively comprising a bulk region and a source region.

FIG. 1B is a detailed view of a cell of the UHV MOS 101 identified by the region 160 in FIG. 1A. FIG. 1B additionally shows a high voltage n-type well (HVNW) 114 and a high voltage p-type deep (HVPD) well 116 disposed in the bulk and source region 146 and a conductive layer 126 in the gate region 144. An n-doped gradient structure comprising a drain side n+ well 132 surrounded by an outer dopant 133 having a dopant concentration that may be different than the drain side n+ well 132 further disposed in a high voltage n- (HVN-) well 128 is disposed in the drain region 148. A metal layer, such as a first metal layer 154, is also shown in FIG. 1B.

FIG. 1C is a more detailed view of the cell of the UHV MOS 101 identified by the region 170 in FIG. 1B. FIG. 1C shows the drain region 148 with an n-doped gradient structure has a n+ well 132 having an outer dopant 133, and a HVN- well 128 in this exemplary embodiment of the invention. In contrast, FIG. 2 shows a drain region 42 of a conventional device having only a drain side n+ well 24 surrounded by an outer dopant 25.

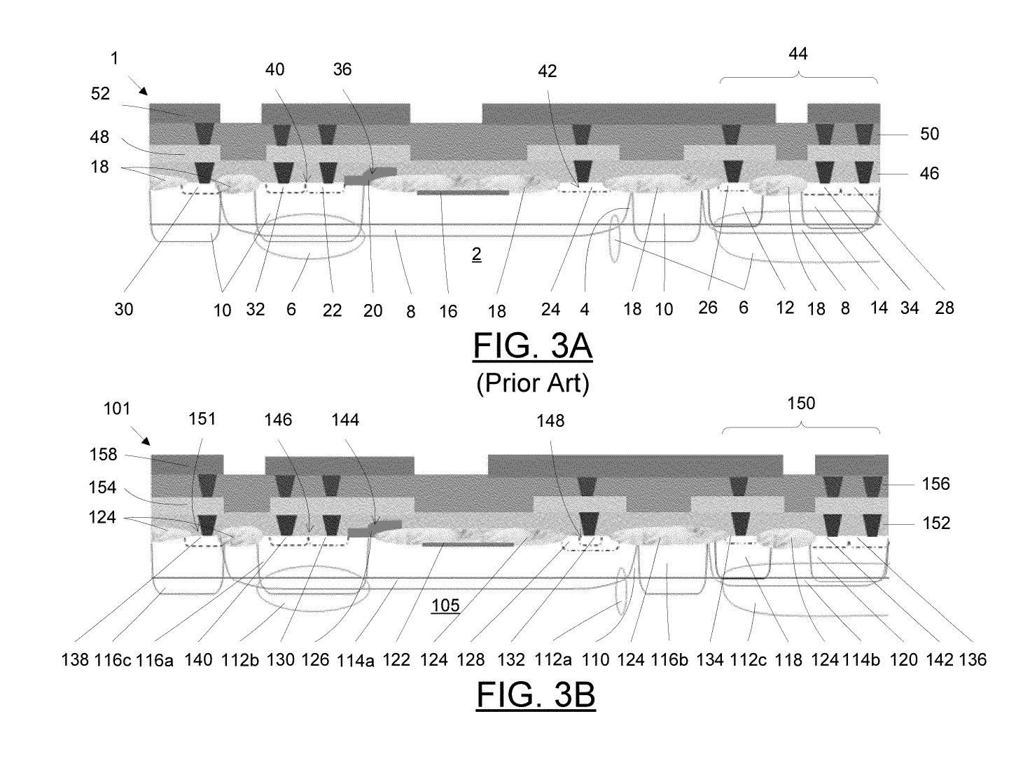

FIG. 3A is a cross-sectional view illustrating a conventional ultra-high voltage n-type metal oxide semiconductor (UHV NMOS) 1. The UHV NMOS 1 is characterized, in part, by a gate region 36, a bulk and source region 40, a drain region 42, and a high side operating region (HSOR) 44. The UHV NMOS 1 comprises a substrate 2 and a p-type epitaxial (p-epi) layer 4 into which is disposed a plurality of n-type buried layers (NBL) 6, a plurality of high voltage n-type wells (HVNW) 8, and a plurality of high voltage p-type deep (HVPD) 10 wells. An n well (NW) 12 and a p well (PW) 14 are disposed in the p-epi layer 4 of the HSOR 44. A p top layer 16 is disposed in a channel region defined between the bulk and source region 40 and the drain region 42. A field oxide (FOX) layer 18 acts to isolate the certain regions of the UHV NMOS 1.

The UHV NMOS 1 also comprises a conductive layer 20, such as, for example, a polysilicon layer disposed on the substrate 2. A series of n+ wells and p+ wells are disposed in the substrate including a source side n+ well 22, a drain side n+ well 24, a first HSOR n+ well 26, a second HSOR n+ well 28, a substrate contact region p+ well 30, a bulk side p+ well 32, and a HSOR p+ well 34.

The conventional UHV NMOS 1 typically also comprises an interlayer dielectric (ILD) layer 46, a first metal layer 48, an inter-metal dielectric (IMD) layer 50, and a second metal layer 52.

In contrast, FIG. 3B is a cross-sectional view illustrating an ultra-high voltage n-type metal oxide semiconductor (UHV NMOS) 101 according to an embodiment of the invention. The UHV NMOS 101 may be characterized, in part, by a gate region 144, a bulk and source region 146 comprising both a bulk region and a source region, a drain region 148, and a high side operating region (HSOR) 150. The UHV NMOS 101 comprises a substrate 105, which may be either a p-type substrate or an n-type substrate, for example, and a p-type epitaxial (p-epi) layer 110. In certain embodiments of the invention, an n-type epitaxial (n-epi) layer may be used instead of the p-epi layer 110. Non-limiting examples of the substrate 105 may include crystalline and/or amorphous silicon, silicon on insulator substrate configurations, an epitaxial silicon in addition to or in combination with the epitaxial layer 110, silicon germanium, among others now known or later adopted in the art.

A plurality of n-type buried layers (NBL) 112 may be disposed throughout the p-epi layer 110 and, optionally, extend into the substrate 105. In the illustrative embodiment of FIG. 3B, a first NBL 112a is disposed at a terminus of the drain region 148 where the drain region 148 abuts an isolation region with an opposite side of the isolation region adjacent to the HSOR 150; a second NBL 112b is disposed at the bulk and source region 146; and at least a part of a third NBL 112c is disposed across the HSOR 150, and a third NBL 112 is disposed about at a terminus of the drain region. In an embodiment of the invention, a part of the second NBL 112b may be disposed in the substrate 105. According to another embodiment of the invention, the second NBL 112b, another part or even another remaining part of the second NBL 112b may be disposed in the p-epi layer 110, for instance.

Furthermore, a plurality of high voltage n wells (HVNW) 114 may be disposed into the p-epi layer 110 and perhaps extending into the substrate 105, according to certain embodiments of the invention. In the illustrative embodiment of FIG. 3B, a first HVNW 114a extends from the bulk and source region 146 across the channel region and to the drain region 148. In this illustrative embodiment, a second HVNW 114b extends substantially across the HSOR 150.

A plurality of high voltage p-type deep (HVPD) wells 116 may be disposed in the p-epi layer 110 and, in some cases, extending into the substrate 105. In the illustrative embodiment of FIG. 3B, a first HVPD well 116a is disposed at the bulk and source region 146, a second HVPD well 116b is disposed in an isolation region between the drain region 148 and the HSOR 150, and a third HVPD well 116c is disposed at a substrate contact region 151 that is aligned with the bulk and source region 146 that is opposite to a side where the bulk and source region 146 is aligned with the channel region.

An n well (NW) 118 and a p well (PW) 120 are disposed in the HSOR 150, while a p top layer 122 is disposed in a channel region extending from the bulk and source region 146 to the drain region 148. A field oxide layer 124 and a conductive layer 126 have also been disposed on the UHV NMOS 101 of FIG. 3B.

In the illustrative embodiment of the invention illustrated in FIG. 3B, an n-dope gradient structure of the drain region comprises a high voltage n- (HVN-) well 128 disposed in the drain region 148. Additionally, the n-doped gradient structure of the drain region comprises a drain side n+ well 132 that has been disposed in the HVN- well 128. Further pursuant to this illustrative embodiment of the invention, the dopant concentrations and perhaps even the type of dopants used in these wells of n-dope gradient structure of the drain region 148 may be different.

In an embodiment of the invention, the dopant concentration of the HVN- well 128 is less than the dopant concentration of the drain side n+ well 132 to define the n-doped gradient structure. In certain embodiments of the invention, the concentration of dopant in the HVN- well 128 is one-tenth of the concentration of dopant in the drain side n+ well 132. According to an embodiment of the invention, a dopant concentration of the drain side n+ well 132 may be from about 1×10¹³ atoms/cm³ to about 1×10¹⁸ atoms/cm³ while a dopant concentration of the HVN- well 128 may be from about 1×10¹² atoms/cm³ to about 1×10¹⁷ atoms/cm³. In certain embodiments of the invention, for example, the concentration of dopant in the drain side n+ well 132 may be on the order of about 1×10¹³ atoms/cm³ while the concentration of dopant in the HVN- well 128 may be on the order of about 10¹² atoms/cm³.

The illustrative embodiment of the UHV NMOS 101 of FIG. 3B also comprises a sub contact p+ well 138, a bulk side p+ well 140, a source side n+ well 130, a first HSOR n+ well 134, a second HSOR n+ well 136, and a HSOR p+ well 142. In certain embodiments of the invention, the second NBL 112b underlies the source side n+ well 130 and the bulk side p well 140. According to the embodiment of FIG. 3B, the dielectric and metallic layers comprise an interlayer dielectric layer (ILD) 152 upon which is disposed a first metal layer 154. An inter-metal dielectric (IMD) layer 156 is disposed between the first metal layer 154 and a second metal layer 158.

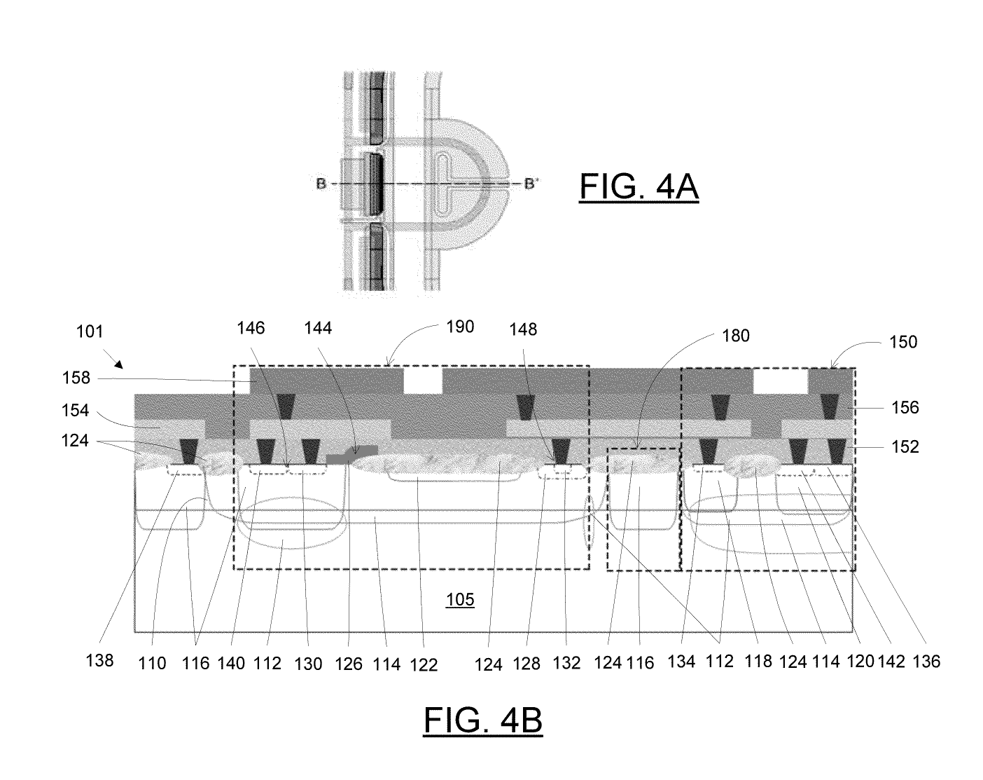

FIG. 4A is a top view of a cell of an UHV NMOS device according to an embodiment of the invention. FIG. 4B a cross-sectional view illustrating the UHV NMOS device taken along the BB′ section line of FIG. 4A. The UHV NMOS of FIG. 4B is substantially similar to the device of FIG. 3B; however, in support of further explanation certain regions of the UHV NMOS 101 are highlighted in FIG. 4B. Generally, the high side operating region (HSOR) 150, without intending to be bound by theory, is configured to perform the necessary level shifting between the gate drive signal from a ground-referenced lower voltage to the high voltages intend to be intended to be delivered by the device.

The UHV NMOS structure 190 is configured to have a breakdown voltage. In certain embodiments of the invention, the breakdown voltage of the UHV NMOS structure 190 is on the order of about 700 V or greater.

The high voltage (HV) interconnection region 180 is disposed between the drain region 148 of the UHV NMOS structure 190 and the HSOR 150. Without intending to be bound by theory, the UHV NMOS structure 190 is configured to have a self-shielding region disposed beneath and substantially aligned with the HV interconnection region 180 to isolate the transistor operations of the UHV NMOS structure 190 and the HSOR 150.

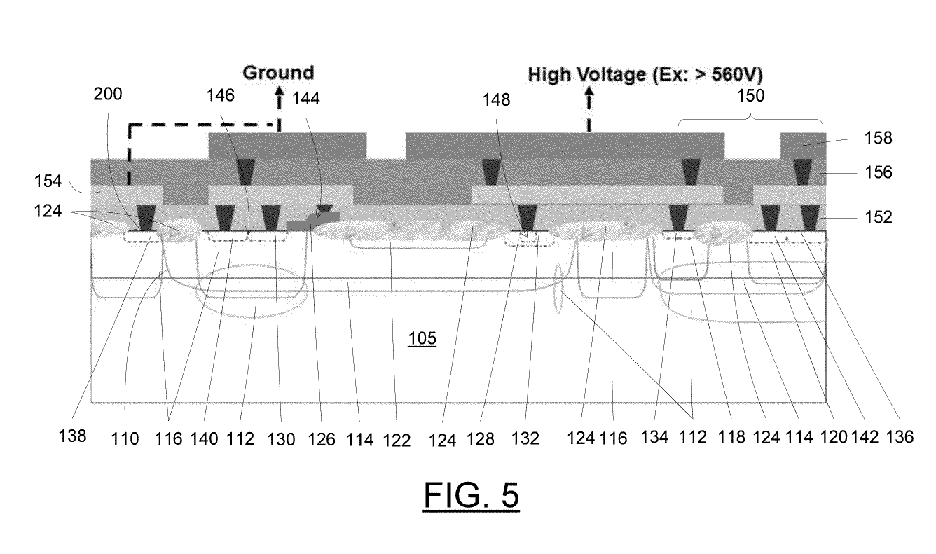

A high temperature reverse bias (HTRB) test may be used as a measure of the reliability of a device. FIG. 5 is a cross-sectional view illustrating an UHV NMOS device according to an embodiment of the invention being subjected to a HTRB test. The HTRB test measures the ability of the device to withstand a reverse bias while being subjected to the maximum ambient temperature that the device components may withstand. The device may also continuously be exposed to HTRB conditions for a period of time, also known as the stress time. In certain tests, the semiconductor devices of the invention were subjected to an HTRB test at a temperature of about 150° C. and high voltages of up to about 560 volts or more over a stress time of 168 hours. According to certain embodiments, the breakdown voltages of a UHV MOS of the invention subjected to these HTRB conditions were substantially not affected demonstrating the reliability and resilience of the inventive structure after being exposed to the HTRB test conditions.

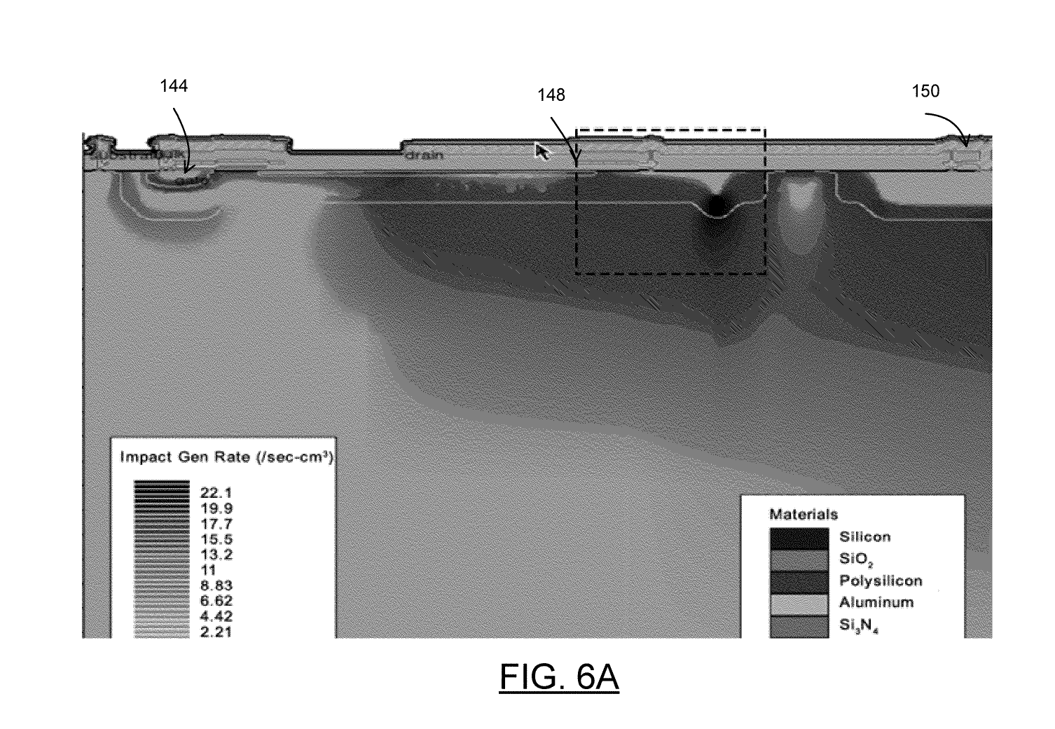

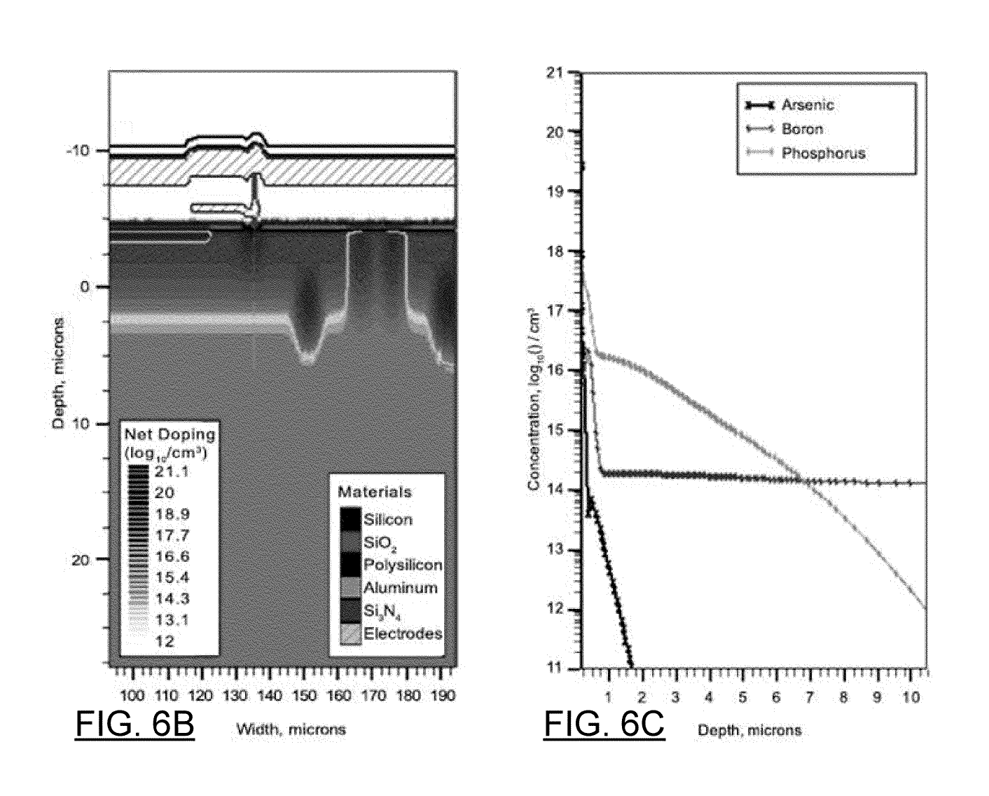

FIG. 6A is a graphical representation of the results of a TCAD simulation of an UHV NMOS device according to an embodiment of the invention. The TCAD simulation of FIG. 6A shows the stress level across the device structure with the weakest point of the device proximate to the drain region 148 of the device. Thus, without intending to be bound by the theory, the results of the HTRB test, which show substantially no deterioration in device performance, suggests the double diffused drain-type structure represented by the drain side n+ well 132 disposed in the HVN- well 128 strengthens and improves the stability of the drain side of the UHV NMOS 101 of the invention.

FIG. 6B is a doping profile for the drain region of a UHV NMOS device according to an embodiment of the invention. In particular, FIG. 6B is representative of the doping profile for the doped gradient structure of the drain region 148 of FIG. 6A. The varying concentrations are represented by the various hues as shown in the profile (using a base 10 logarithmic scale of the number of atoms/cm³) for varying depths as measured from a top surface of the substrate and various widths in the drain region 148 of FIG. 6A. For example, as shown in FIG. 6B, the greatest concentration of dopant in the doped gradient structure of the drain region (i.e., in the drain side n+ well) is about 4×10¹⁶ atoms/cm³ while the lowest concentration of dopant in the doped gradient structure of the drain region (i.e., in the HVN- well) is about 5×10¹⁵ atoms/cm³.

FIG. 6C are doping profiles for various types of dopants of the doped gradient structure of the drain region of a UHV NMOS device according to various embodiments of the invention. The y axis represents the concentration of dopant using a base 10 logarithmic scale of the number of atoms/cm³ while the x-axis is representative of a depth measured from a surface of the substrate. In certain embodiments of the invention, the concentration of arsenic may vary from about 5×10¹³ atoms/cm³ to about 1×10¹⁸ atoms/cm³ in the drains side n+ well and from less than about 1×10¹¹ atoms/cm³ to about 5×10¹³ atoms/cm³ in the HVN-well. In certain other embodiments of the invention, the concentration of boron may vary from greater than about 2×10¹⁴ atoms/cm³ to about 2.5×10¹⁶ atoms/cm³ in the drains side n+ well and from about 1×10¹⁴ atoms/cm³ to about 2×10¹⁴ atoms/cm³ in the HVN- well. In yet certain other embodiments of the invention, the concentration of phosphorus may vary from about 2×10¹⁶ atoms/cm³ to about 4×10¹⁷ atoms/cm³ in the drains side n+ well and from about 1×10¹² atoms/cm³ to about 2×10¹⁶ atoms/cm³ in the HVN- well. The graphs of the FIG. 6C may be merged when two or more types of dopants are used to define a doped gradient structure of the drain region according to certain embodiments of the invention.

Another aspect of the invention provides a method of fabricating or manufacturing a semiconductor device. Generally, the method of fabricating a semiconductor device, according to certain embodiments of the invention, may include preparing substrate of silicon wafer or providing a silicon wafer having a substrate. Specifically, the methods of fabricating a semiconductor device of the invention are directed to fabricating a UHV MOS device having a doped gradient structure.

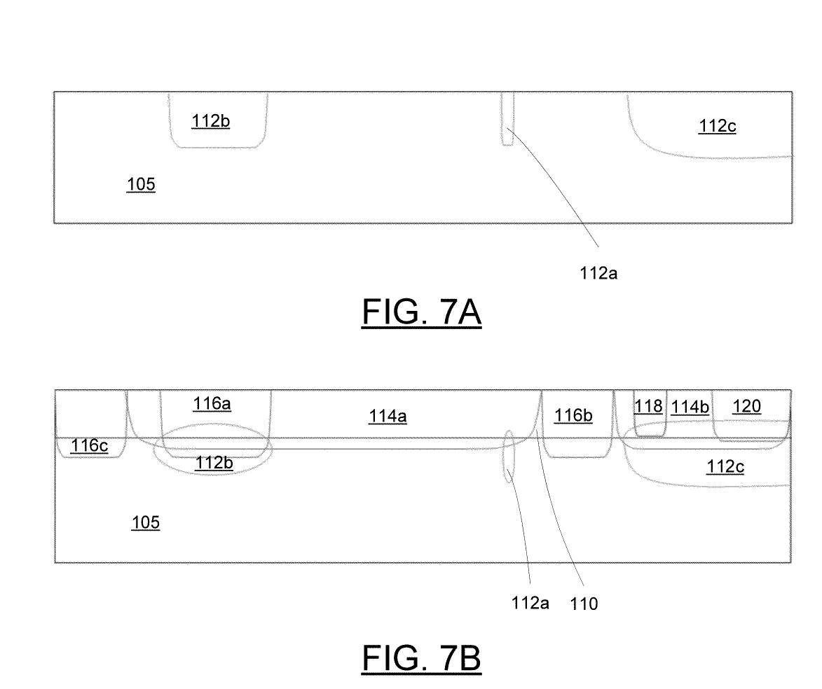

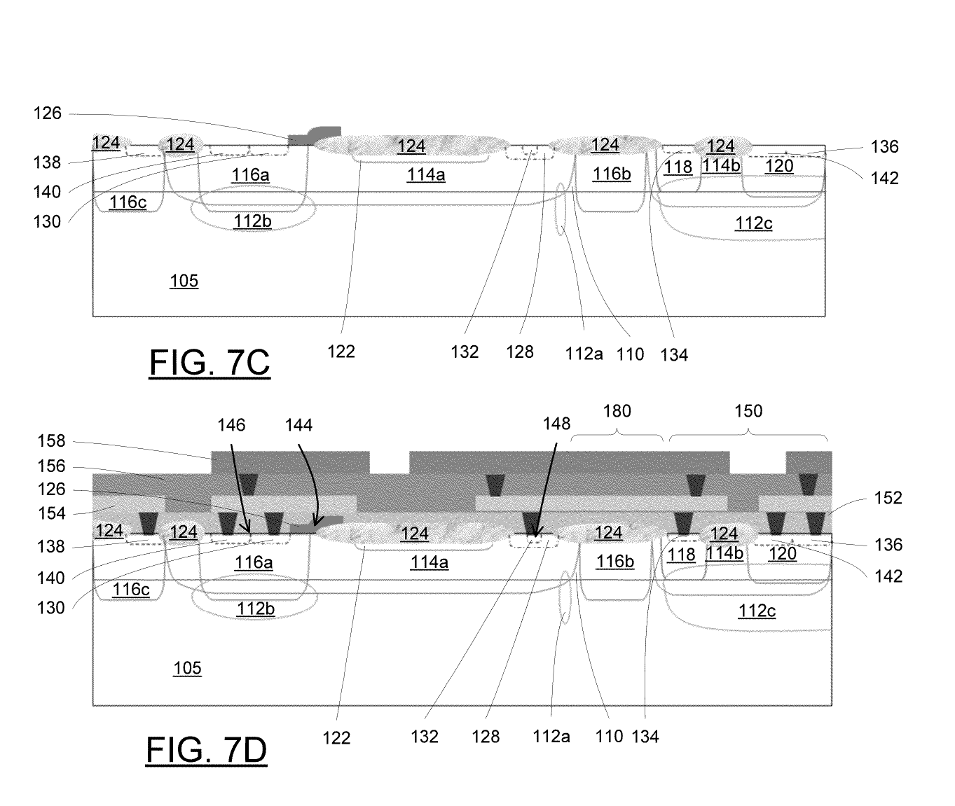

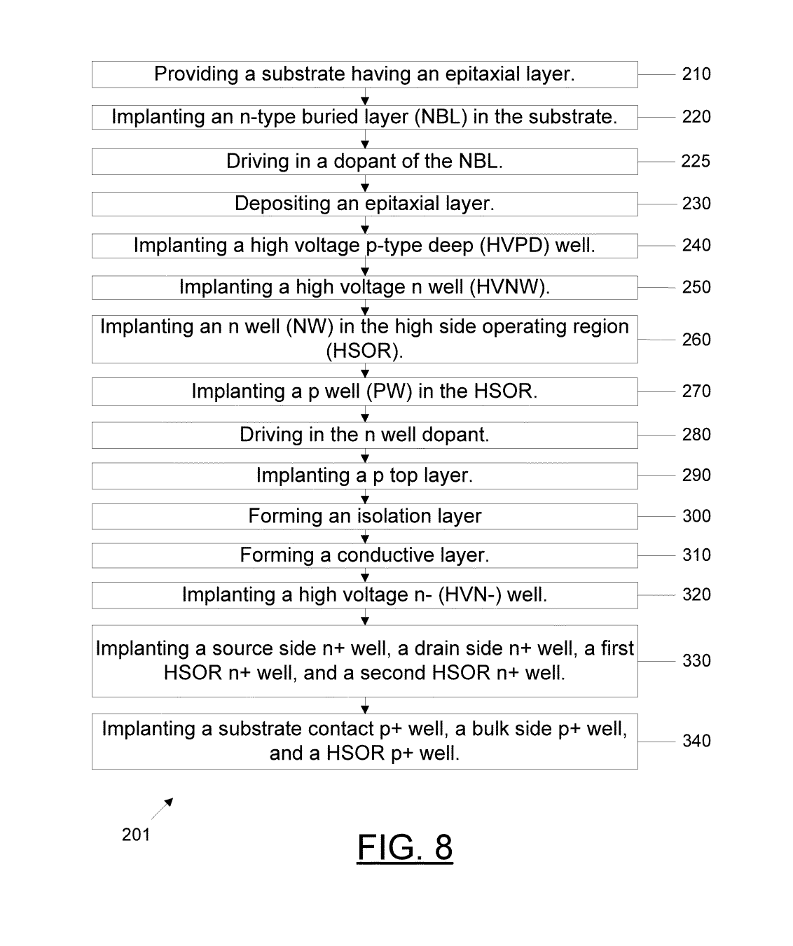

FIG. 8 is a process flow diagram showing the various steps of fabricating an UHV NMOS device according to an embodiment of the invention. According to FIG. 8, the method for fabricating a semiconductor device 201 comprises providing a substrate 210, implanting an n-type buried layer (NBL) 220 into the substrate, and driving in the dopant of the NBL 225. Certain of the steps generally described in this method may themselves comprise other sub-steps that have not necessarily been identified. For example, steps directed to implanting a dopant where such an implantation occurs using photolithography, for example, will also including providing a masking layer and removing such a layer once the implanting step has been performed. Such additional steps are understood by a person of ordinary skill in the art having the benefit of this disclosure. FIG. 7A is a cross-sectional view illustrating the UHV NMOS after undergoing the providing, implanting, and driving steps already described herein according to an embodiment of the invention.

The method for fabricating a semiconductor device 201 may additionally comprise depositing an epitaxial layer 230, for example, a p-type epitaxial (p-epi) layer; implanting a high voltage p-type deep (HVPD) well 240, implanting a high voltage n-type well (HVNW) 250; implanting an n well (NW) in the high side operating region (HSOR) 260; implanting a p well (PW) in the HSOR 270; and driving in the NW dopant 280. FIG. 7B is a cross-sectional view illustrating the UHV NMOS after undergoing these steps of the method for fabricating a semiconductor device 201 according to an embodiment of the invention.

The method for fabricating a semiconductor device 201 may additionally comprise implanting a p top layer 290; forming an isolation region 300 such as, for example, by growing a field oxide (FOX) layer; forming a conductive layer 310, such as a polysilicon layer according to an embodiment of the invention; implanting a high voltage n- (HVN-) well 320; implanting a source side n+ well, a drain side n+ well, a first high side operating region (HSOR) n+ well, and a second HSOR n+ well 330; and implanting a sub contact p+ well, a bulk side p+ well, and a HSOR p+ well 340. According to an embodiment of the invention, the area where the n-type dopant implantation of the HVN- may occur may, at least in part, be defined by the FOX layer. In other embodiments of the invention, photolithography may be used to further define the implant area for the HVN- ion implant.

According to certain embodiments of the invention, the isolation region may include one or more shallow trench isolation (STI) structures. In certain embodiments of the invention, the isolation region may comprise a field oxide layer and one or more STI structures.

In an embodiment of the invention, the tilt angle, which defines the angle the HVN- ions are implanted relative to a vertical line that is substantially perpendicular to the surface of the substrate where the ion is to be implanted, is about zero. I.e., in certain embodiments of the invention, the HVN- ions are implanted with approximately no tilt angle. In other embodiments of the invention, the title angle is at least about 0.5 degree, at least about 1.6 degrees, at least about 7 degrees, about 7 degrees to about 30 degrees, or up to about 60 degrees. FIG. 7C is a cross-sectional view illustrating the UHV NMOS after undergoing these steps of the method for fabricating a semiconductor device 201 according to an embodiment of the invention.

The method of fabricating a semiconductor device 201 may additionally comprise the steps of depositing an interlayer dielectric (ILD), depositing a first metal layer, depositing an inter-metal dielectric (IMD) layer, and depositing a second metal layer, and forming a pad pattern in the UHV NMOS. FIG. 7D is a cross-sectional view illustrating the UHV NMOS after undergoing these steps of the method for fabricating a semiconductor device 201 according to an embodiment of the invention.

The UHV MOS devices of the invention may be applied, for example, in mixed-mode or analog circuit designs. Non-limiting examples of where the UHV MOS devices of the invention may have applicability include LED lighting, energy saving lamps, electrical ballast devices, and drivers for motors and other equipment. Without intending to be limiting, the reliability of the inventive UHV MOS of the invention as demonstrated using the HTRB test makes the device suitable for these and many other high voltage applications.

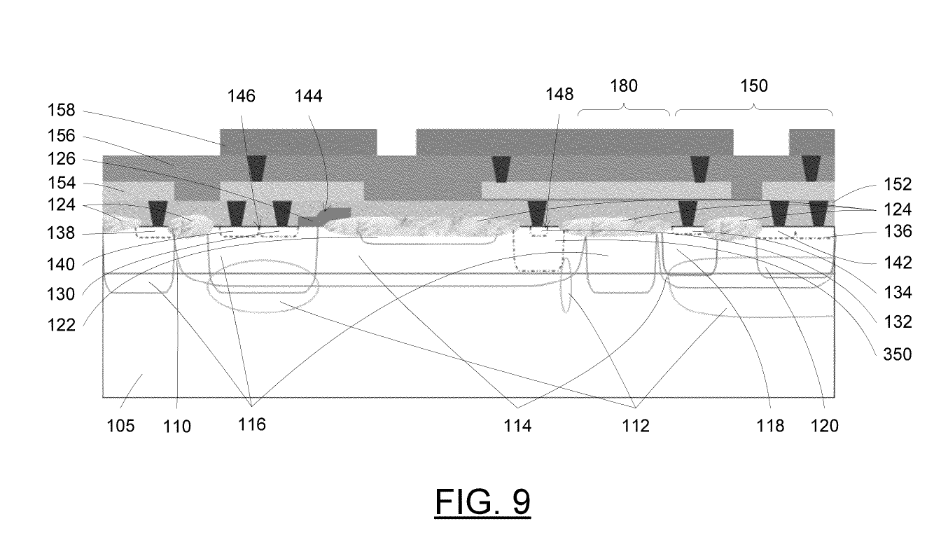

The inventors have envisioned many other types of structure designs that lead to an improved stability in the vicinity of the drain region. FIG. 9 is a cross-sectional view illustrating an UHV NMOS according to another embodiment of the invention. The structure of the UHV NMOS of FIG. 9 resembles the structure of the UHV NMOS of FIG. 7D in every respect except that a high voltage n-type deep (HVND) well 350 replaces the HVN- well 128 of the drain region 148.

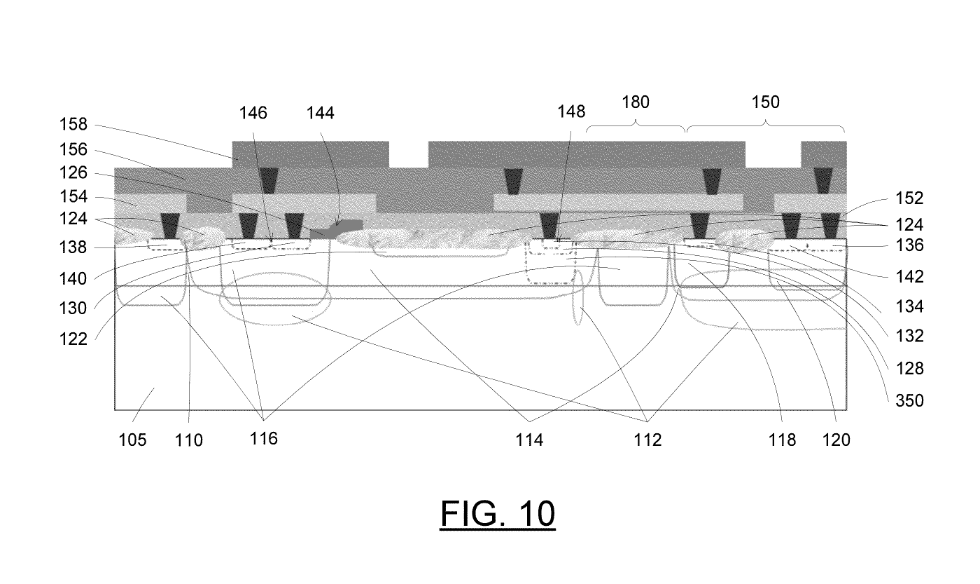

FIG. 10 is a cross-sectional view illustrating an UHV NMOS according to another embodiment of the invention. The structure of the UHV NMOS of FIG. 10 resembles the structure of the UHV NMOS of FIG. 7D in every respect except that a multi-layer n-type doping structure in the drain region has been adopted. The illustrative exemplary embodiment of FIG. 10 shows a high voltage n-type deep (HVND) well 350 and a HVN-well 128 are disposed in the drain region 148. A drain side n+ well 132 is disposed in the HVN- well 128.

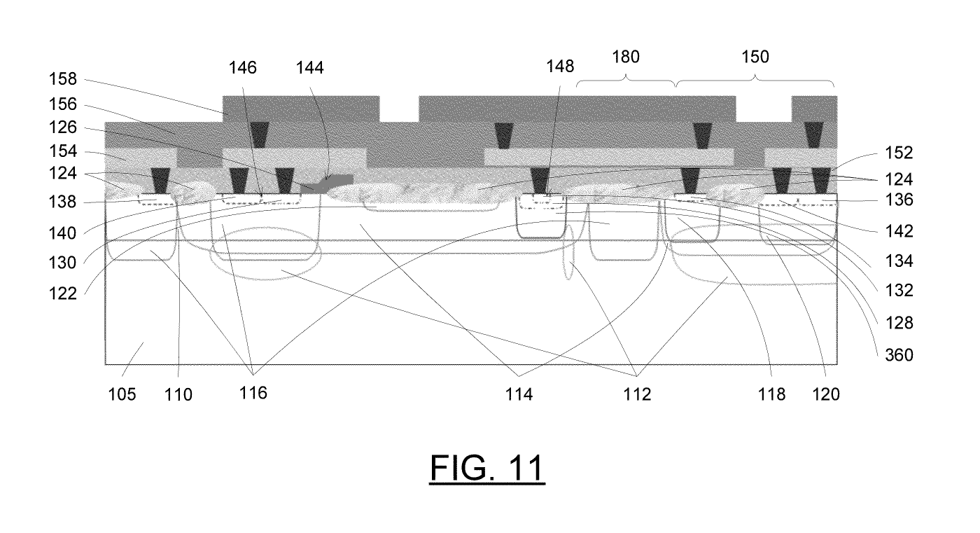

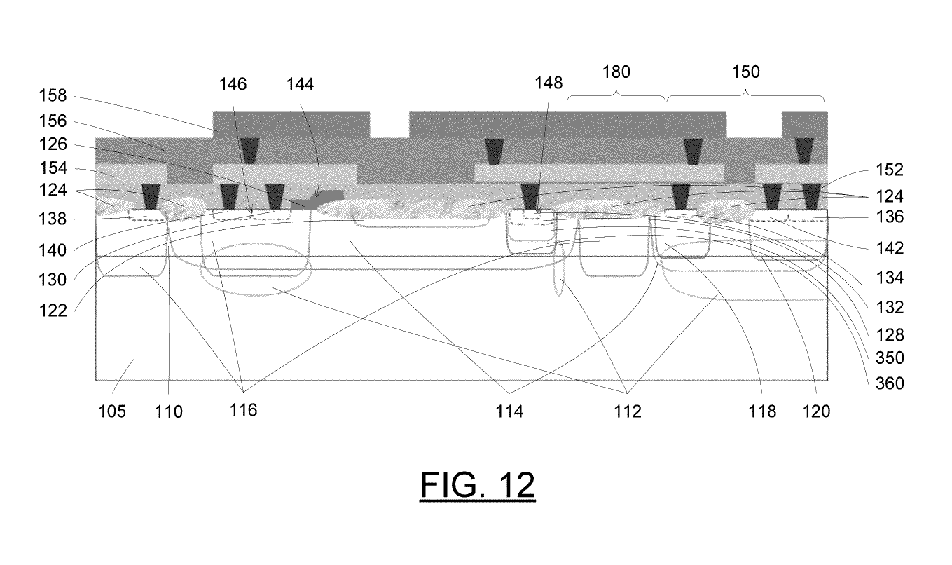

FIG. 11 is a cross-sectional view illustrating an UHV NMOS according to another embodiment of the invention. The structure of the UHV NMOS of FIG. 11 resembles the structure of the UHV NMOS of FIG. 7D in every respect except that another multi-layer n-type doping structure in the drain region has been adopted. The illustrative exemplary embodiment of FIG. 11 shows an n-type well (NW) 360 and a HVN- well 128 are disposed in the drain region 148. A drain side n+ well 132 is disposed in the HVN- well 128.

FIG. 12 is a cross-sectional view illustrating an UHV NMOS according to another embodiment of the invention. The structure of the UHV NMOS of FIG. 12 resembles the structure of the UHV NMOS of FIG. 7D in every respect except that yet another multi-layer n-type doping structure in the drain region has been adopted. The illustrative exemplary embodiment of FIG. 12 shows an NW 360, a HNVD well 350, and a HVN- well 128 are disposed in the drain region 148. A drain side n+ well 132 is disposed in the HVN- well 128.

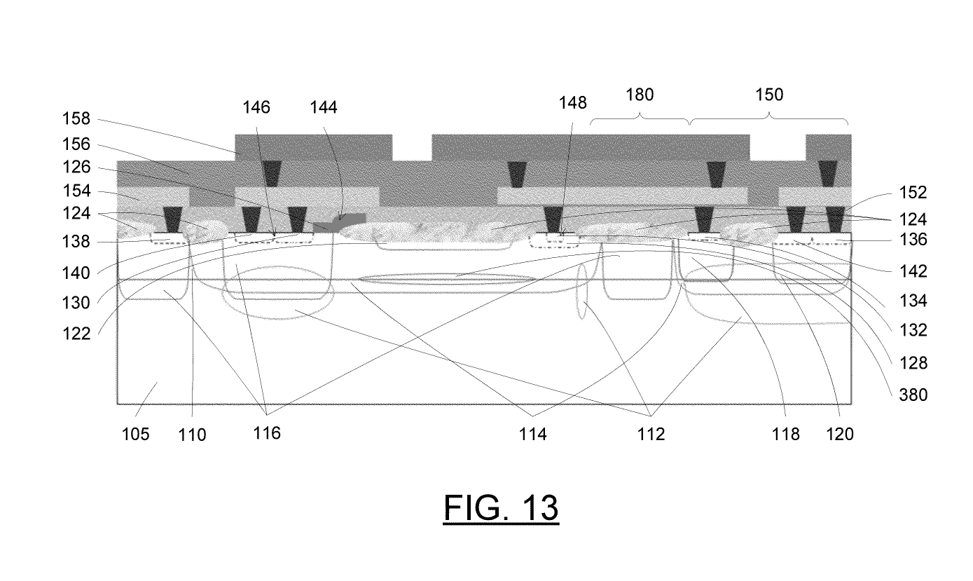

FIG. 13 is a cross-sectional view illustrating an UHV NMOS according to another embodiment of the invention. The structure of the UHV NMOS of FIG. 13 resembles the structure of the UHV NMOS of FIG. 7D in every respect except that the UHV NMOS of FIG. 13 has an additional p top layer 380. Further pursuant to this exemplary embodiment, the dopant for the additional p top layer 380 may be implanted in the HVNW 144 of the channel region followed by further driving in the additional p top layer 380 to the desire depth in the substrate 105. According to the illustrative embodiment of FIG. 13, the additional p top layer may be positioned somewhere within the interface of the substrate 105 and the p-epi layer 110. According to other embodiments of the invention, the additional p top layer 380 may be positioned anywhere within the HVNW 144 of the channel region. In yet other embodiments of the invention, the additional p top layer 380 may be positioned in the substrate 105 below the interface of the substrate 105 and the p-epi layer 110.

An embodiment of the invention provides a structure having three or more p top layers. Each of the p top layers may be implanted and driven into a desired position in the substrate as further described herein. The positions of these three or more p top layers may be anywhere within the substrate as also further described herein.

In yet other embodiments, the UHV NMOS of the invention has a single p top layer, but the p top layer may be implanted and driven into the substrate using the procedures as further described herein. Further pursuant to this embodiment of the invention, the p top layer may be configured to be positioned anywhere within the HVNW 144 of the channel region; just above, at, or just below where the p-epi layer 110 interfaces with the substrate 105; or within only the substrate 105.

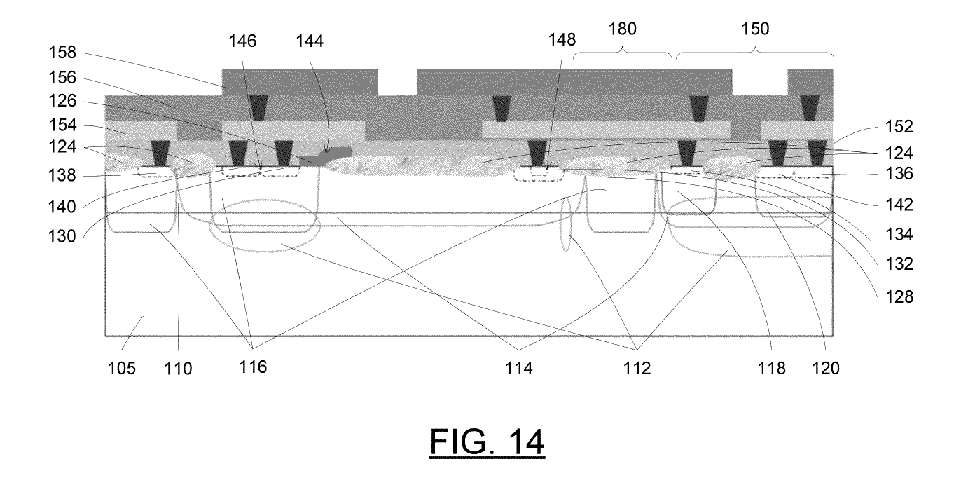

FIG. 14 is a cross-sectional view illustrating an UHV NMOS device according to another embodiment of the invention. The structure of the UHV NMOS of FIG. 14 resembles the structure of the UHV NMOS of FIG. 7D in every respect except that the UHV NMOS of FIG. 14 does not have a p top layer 122.

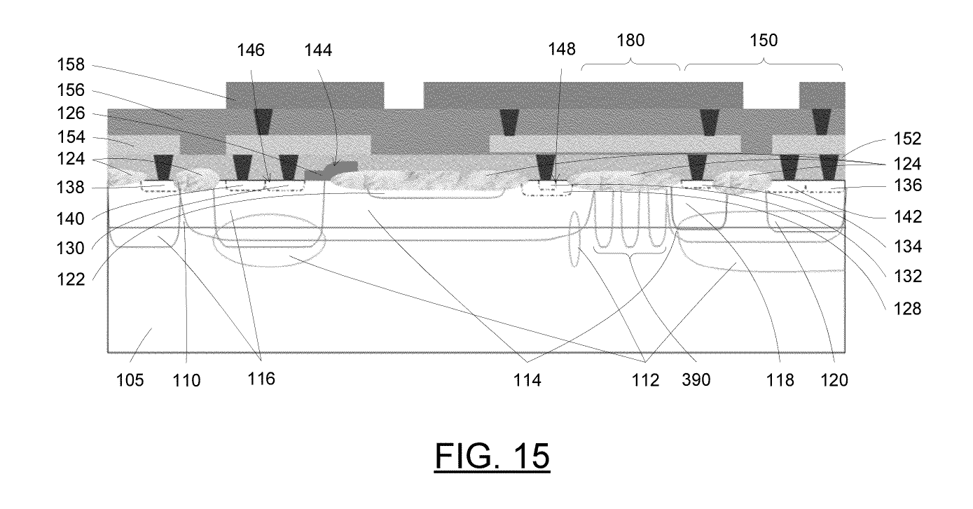

FIG. 15 is a cross-sectional view illustrating an UHV NMOS device according to another embodiment of the invention. The structure of the UHV NMOS of FIG. 15 resembles the structure of the UHV NMOS of FIG. 7D in every respect except that the HVPD 116 of FIG. 7D in the HV interconnection region 180 has been implanted as two or more discrete HVPD well segments 390. For example, the UHV NMOS of FIG. 15 has three discrete HVPD well segments 390. According to an embodiment of the invention, the size and shape of each of the two or more discrete HVPD well segments may vary or be the same size and/or shape. Pursuant to the embodiments having more than two discrete HVPD well segments, the distances between each of the discrete HVPD well segments may be substantially the same or different.

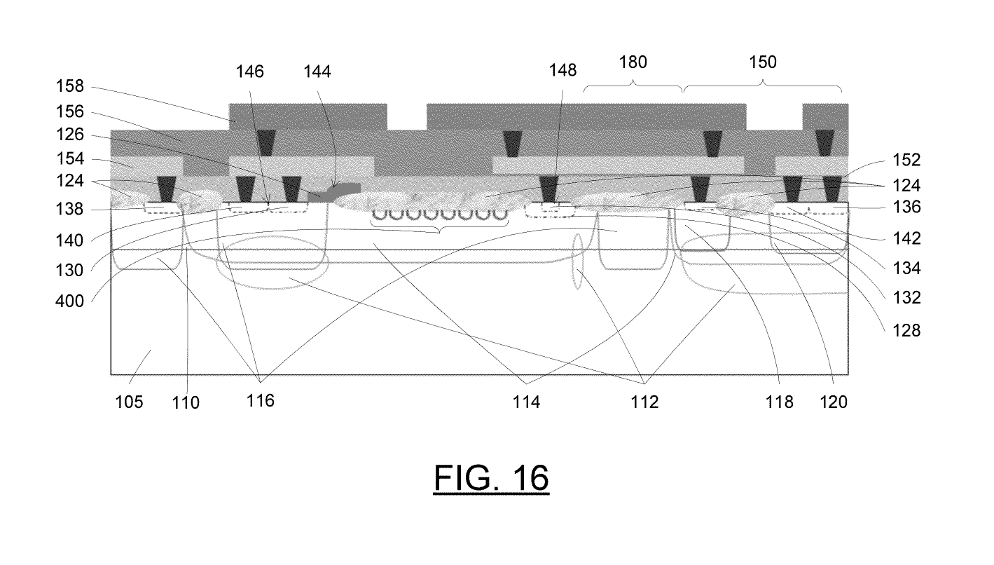

FIG. 16 is a cross-sectional view illustrating an UHV NMOS device according to another embodiment of the invention. The structure of the UHV NMOS of FIG. 16 resembles the structure of the UHV NMOS of FIG. 7D in every respect except that p top layer of FIG. 16 has two or more discrete p top segments 400. For example, the UHV NMOS of FIG. 16 has eight separate discrete p top segments 400. According to an embodiment of the invention, the size and shape of each of the two or more discrete p top segments may vary or be of the same size and/or shape. The two or more discrete p top segments 400 may be positioned at substantially the same depth with the substrate or the depths of the discrete p top segments 400 may vary within the substrate. Pursuant to the embodiments having more than two discrete p top segments, the distances between each of the discrete p top segments may be substantially the same or different.

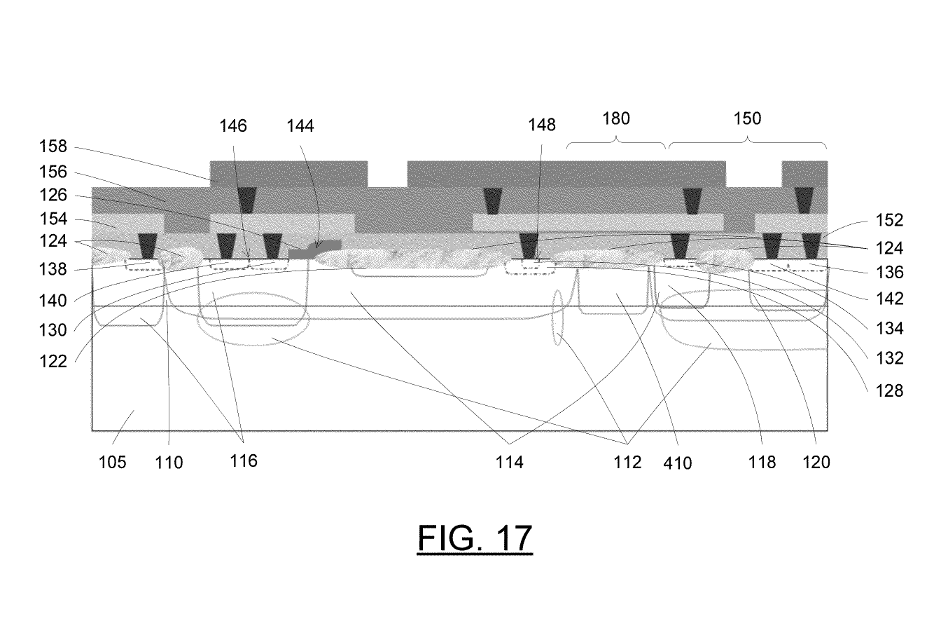

FIG. 17 is a cross-sectional view illustrating an UHV NMOS according to another embodiment of the invention. The structure of the UHV NMOS of FIG. 17 resembles the structure of the UHV NMOS of FIG. 7D in every respect except that a HV interconnection p-type well (PW) 410 is used instead of the HVPD 116 in the HV interconnection region 180 of FIG. 7D.

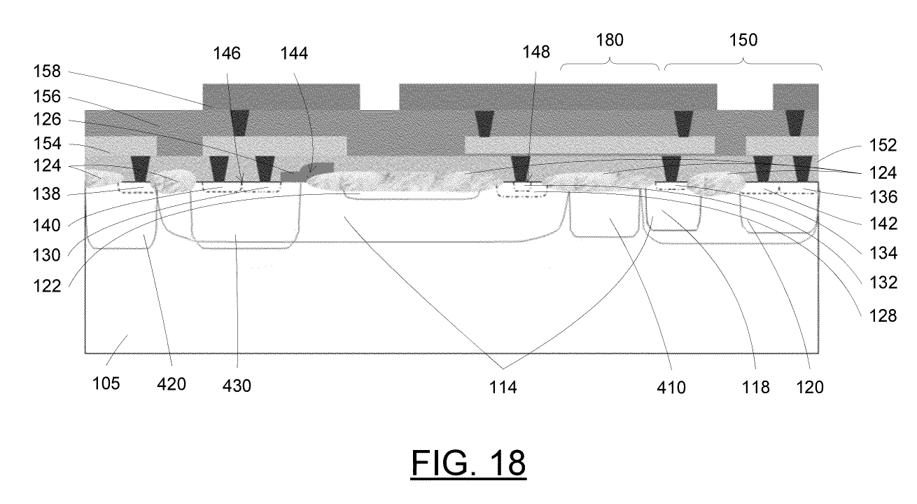

FIG. 18 is a cross-sectional view illustrating an UHV NMOS according to another embodiment of the invention. In contrast to the UHV NMOS structure of FIG. 7D, the UHV NMOS structure of FIG. 18 does not have p-epi layer or the NBL layers shown in FIG. 7D. Additionally, the UHV NMOS structure of FIG. 18 adopts a HV interconnection p-type well (PW) 410, a sub contact region PW 420, and a bulk and source PW 430 instead of the HVPDs 116 of FIG. 7D. The UHV NMOS device illustrated in FIG. 18 provides a low cost solution using a shallow PW process that may be suitable to some high voltage applications.

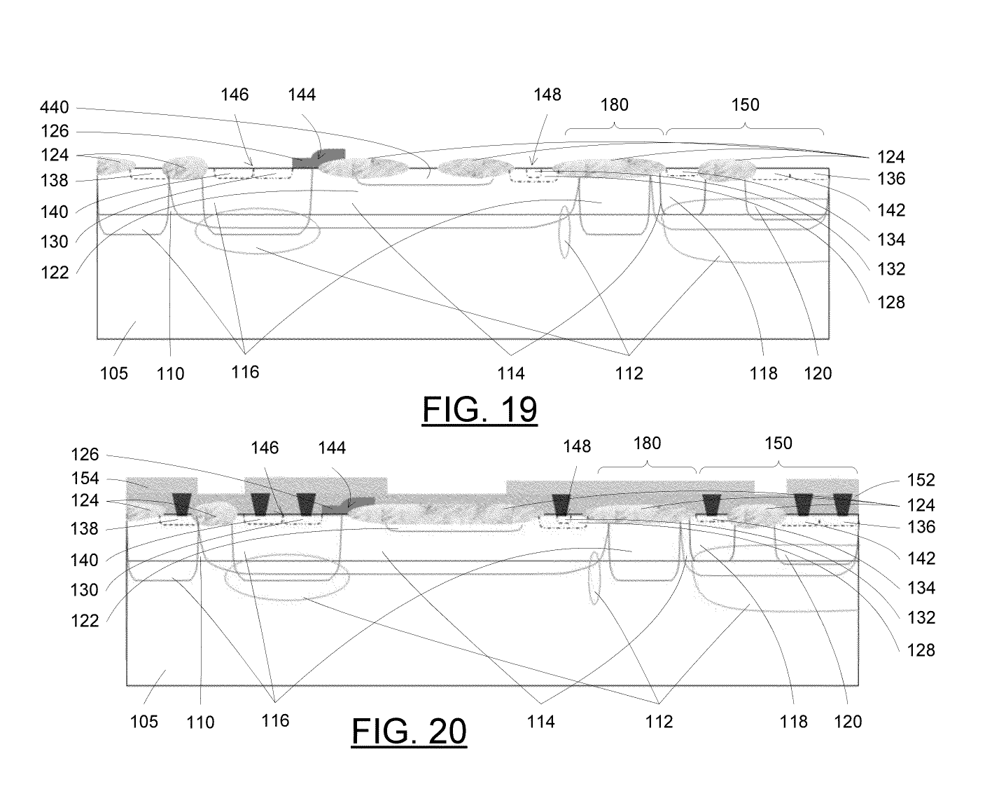

FIG. 19 is a cross-sectional view illustrating an UHV NMOS according to another embodiment of the invention. The structure of the UHV NMOS of FIG. 19 is a variation on the structure of the UHV NMOS of FIG. 7D showing that the FOX layer 124 may have varying configurations. For example the FOX layer 124 of FIG. 19 is configured to provide partial masking of the substrate in the channel region whereby another dopant may be implanted in substrate to form an implant layer 440.

FIG. 20 is a cross-sectional view illustrating an UHV NMOS according to another embodiment of the invention. The structure of the UHV NMOS device of FIG. 20 shows that only one metal layer may be used according to an embodiment of the invention.

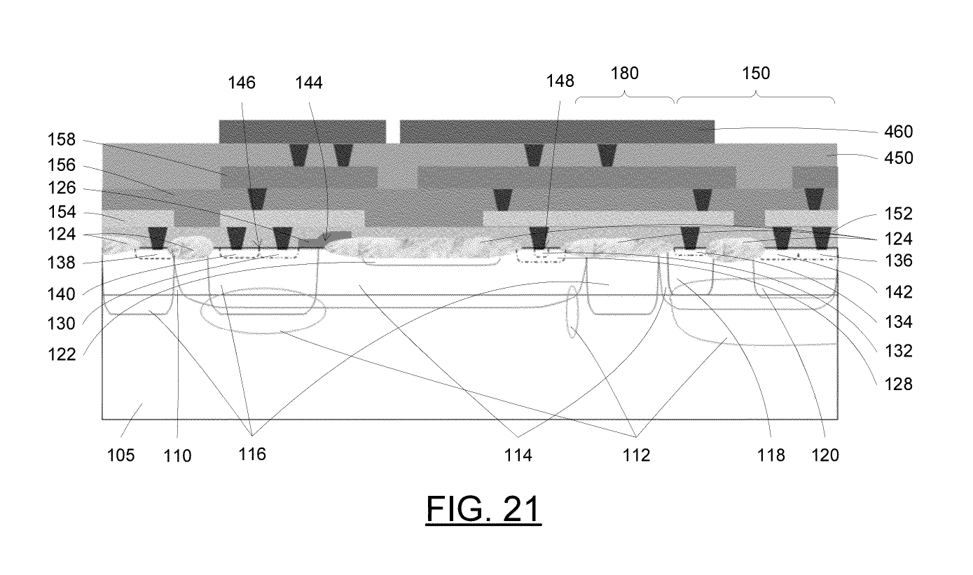

FIG. 21 is a cross-sectional view illustrating an UHV NMOS according to another embodiment of the invention. The structure of the UHV NMOS device of FIG. 21 shows a second inter-metal dielectric (IMD) layer 450 is disposed be the second metal layer 158 and a third metal layer 460. In yet other embodiments of the invention, a UHV NMOS device may be configured to have more than three metal layers.

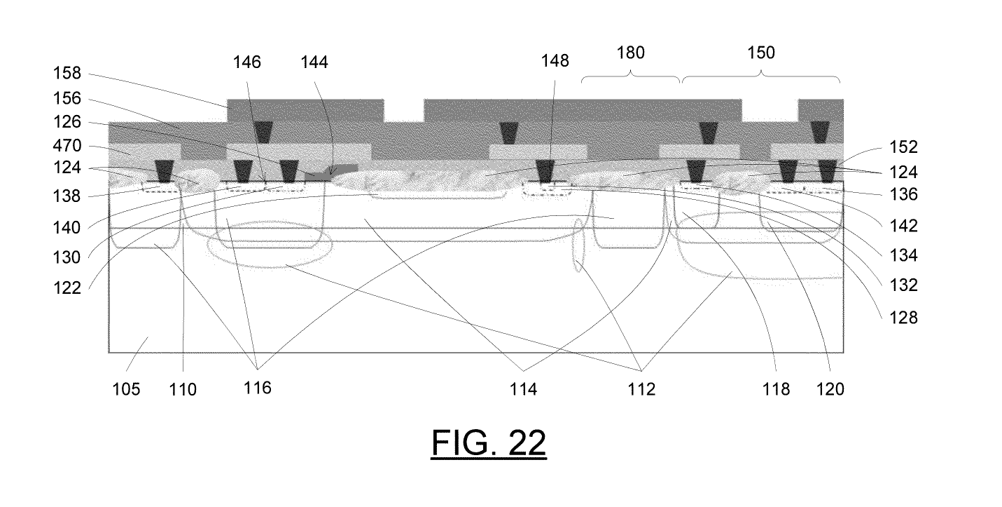

FIG. 22 is a cross-sectional view illustrating an UHV NMOS according to another embodiment of the invention. The structure of the UHV NMOS of FIG. 22 resembles the structure of the UHV NMOS of FIG. 7D in every respect except that a first metal layer 470 of the UHV NMOS of FIG. 22 is different from the first metal layer 154 of FIG. 7D. The first metal layer 470, as shown in FIG. 22, is configured to allow only the second metal layer 158 to lie above the HV interconnection region 180.

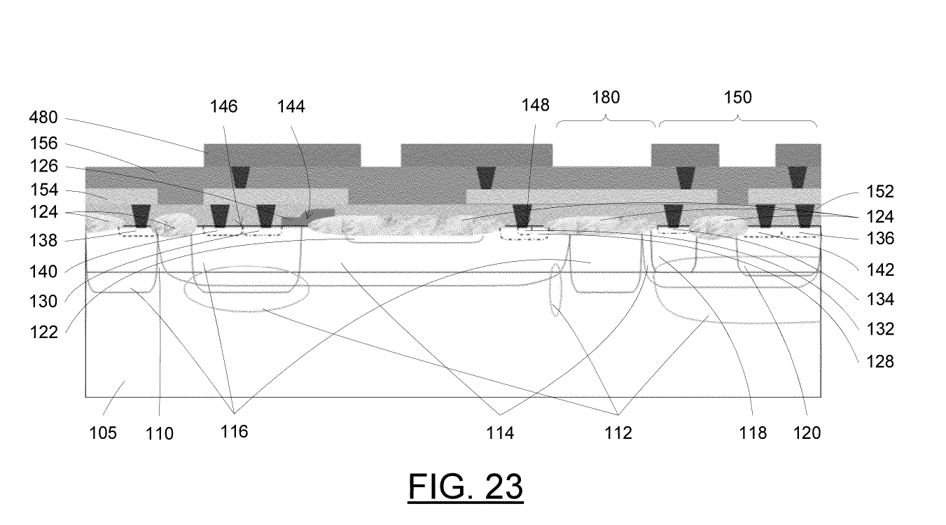

FIG. 23 is a cross-sectional view illustrating an UHV NMOS according to another embodiment of the invention. The structure of the UHV NMOS of FIG. 23 resembles the structure of the UHV NMOS of FIG. 7D in every respect except that a second metal layer 480 of the UHV NMOS of FIG. 23 is different from the second metal layer 158 of FIG. 7D. The second metal layer 480, as shown in FIG. 23, is configured to allow only the first metal layer 154 to lie above the HV interconnection region 180.

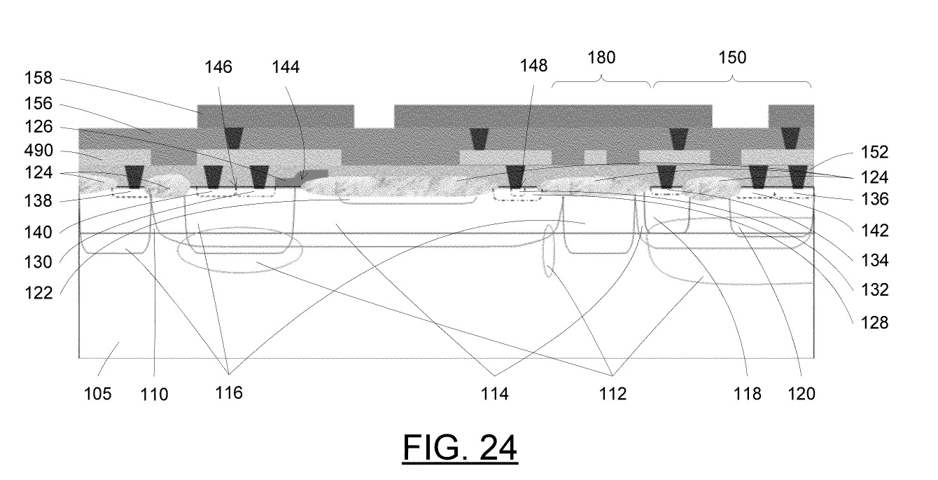

FIG. 24 is a cross-sectional view illustrating an UHV NMOS according to another embodiment of the invention. The structure of the UHV NMOS of FIG. 24 resembles the structure of the UHV NMOS of FIG. 7D in every respect except that a patterned region of a first metal layer 490 of the UHV NMOS of FIG. 24 is configured to lie above the HV interconnection region 180.

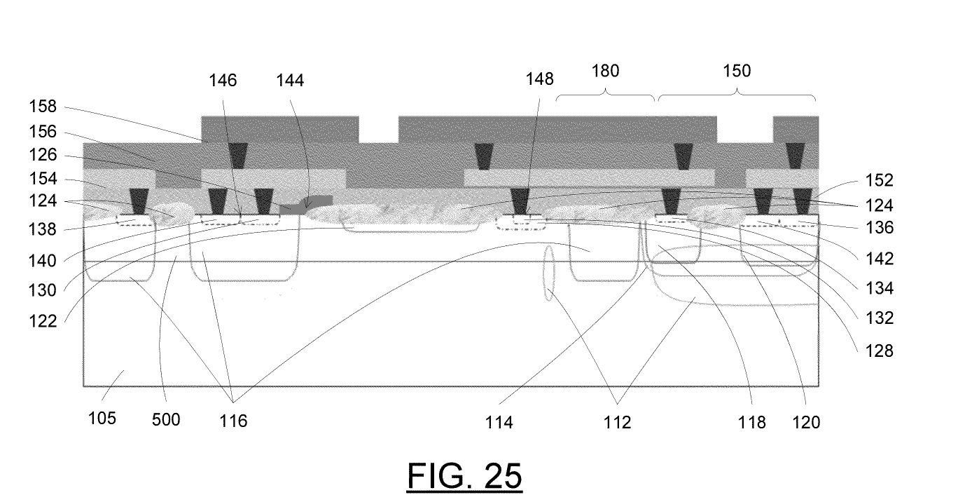

FIG. 25 is a cross-sectional view illustrating an UHV NMOS according to another embodiment of the invention. The structure of the UHV NMOS of FIG. 25 resembles the structure of the UHV NMOS of FIG. 7D in every respect except that an n-type epitaxial (n-epi) layer 500 replaces the p-epi layer 110 of the UHV NMOS of FIG. 7. Without intending to be bound by the principle, the use of the n-epi layer 500 eliminates the need for the NBL 112 of the source region the HVNW 114 in the channel region. Additionally, the use of the n-epi layer 500 requires that the operation bias is constant—i.e., the voltage of at the source and the sub contact are substantially equivalent.

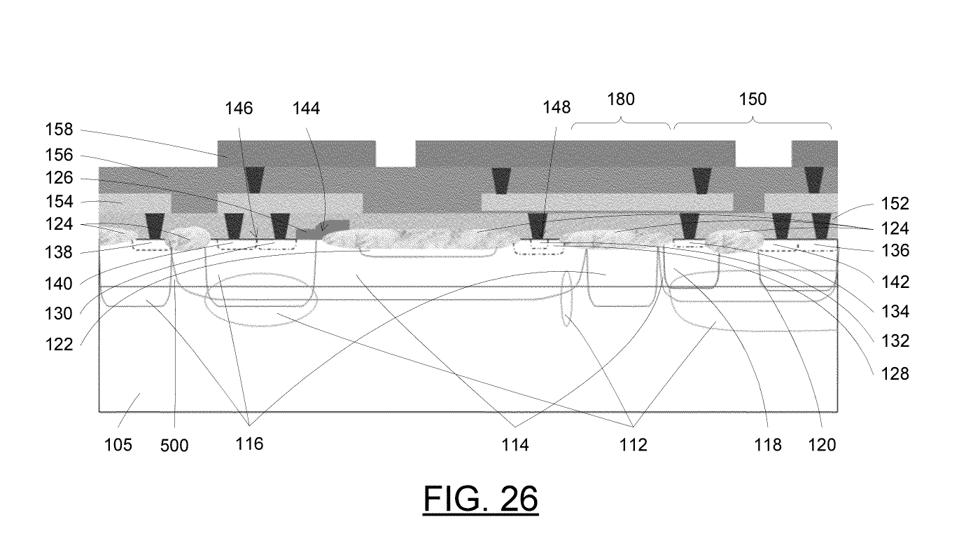

FIG. 26 is a cross-sectional view illustrating an UHV NMOS according to another embodiment of the invention. The structure of the UHV NMOS of FIG. 26 mostly resembles the structure of the UHV NMOS of FIG. 7D except that an n-type epitaxial (n-epi) layer 500 replaces the p-epi layer 110 of the UHV NMOS of FIG. 7. However, the UHV NMOS of FIG. 26 has been adapted such that the NBL 112 of the source region and the HVNW 114 in the channel region remain a part of the device structure.

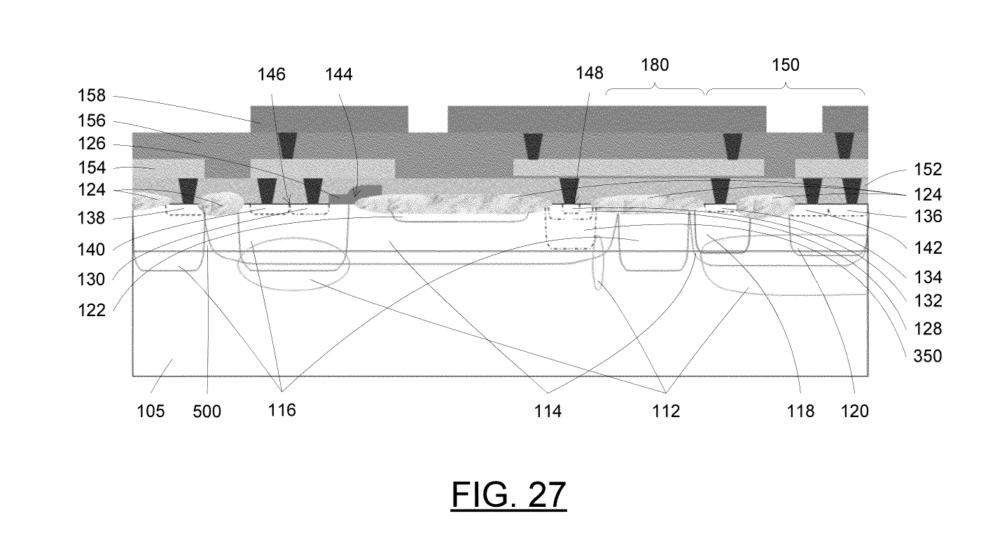

FIG. 27 is a cross-sectional view illustrating an UHV NMOS according to another embodiment of the invention. In comparison the UHV NMOS of FIG. 7D, the UHV NMOS of FIG. 27 comprise an n-epi layer 500 and not a p-epi layer 110. Additionally, the UHV NMOS of FIG. 27 adopts a multi-layer n-type doping structure in the drain region 148. According to the illustrative embodiment of FIG. 27, a HVND well 350 and a HVN- well 128 are disposed in the drain region 148. A drain side n+ well 132 is disposed in the HVN- well 128. In certain other embodiments of the invention, both an NW and a HVND well 350 may be used (not show). In yet other embodiments of the invention, an NW may be used instead of the HVND well 350 (not shown).

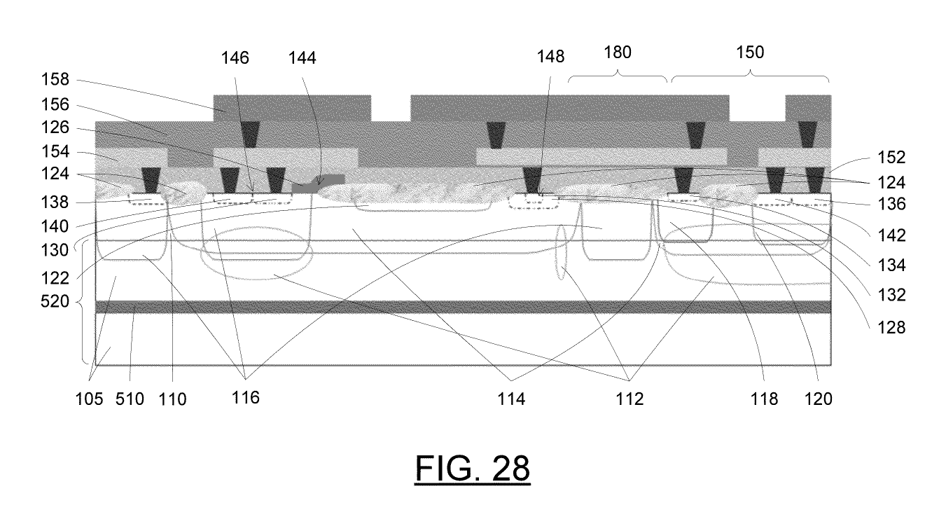

FIG. 28 is a cross-sectional view illustrating an UHV NMOS according to another embodiment of the invention. Instead of merely using a substrate 105 as shown in the UHV NMOS of FIG. 7D, the UHV NMOS of FIG. 28 adopts a silicon-on-insulator (SOI) structure 520 having a substrate 105 and a buried oxide layer 510 disposed therein.

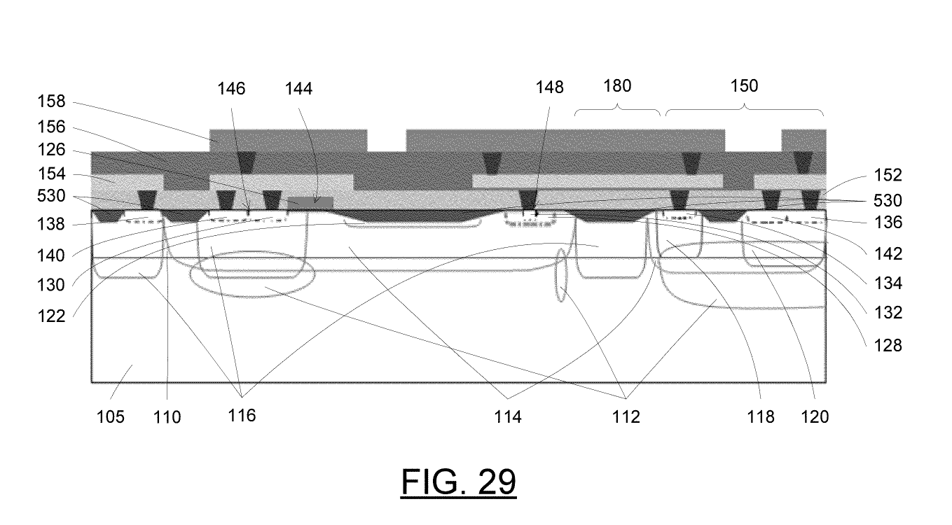

FIG. 29 is a cross-sectional view illustrating an UHV NMOS according to another embodiment of the invention. The structure of the UHV NMOS of FIG. 29 resembles the structure of the UHV NMOS of FIG. 7D in almost every respect except that shallow trench isolation (STI) structures 530 are used in the UHV NMOS of FIG. 29 in place of the FOX layer 124 of the UHV NMOS of FIG. 7D. The structure of FIG. 29 is particularly useful in scaling down the size of the UHV NMOS

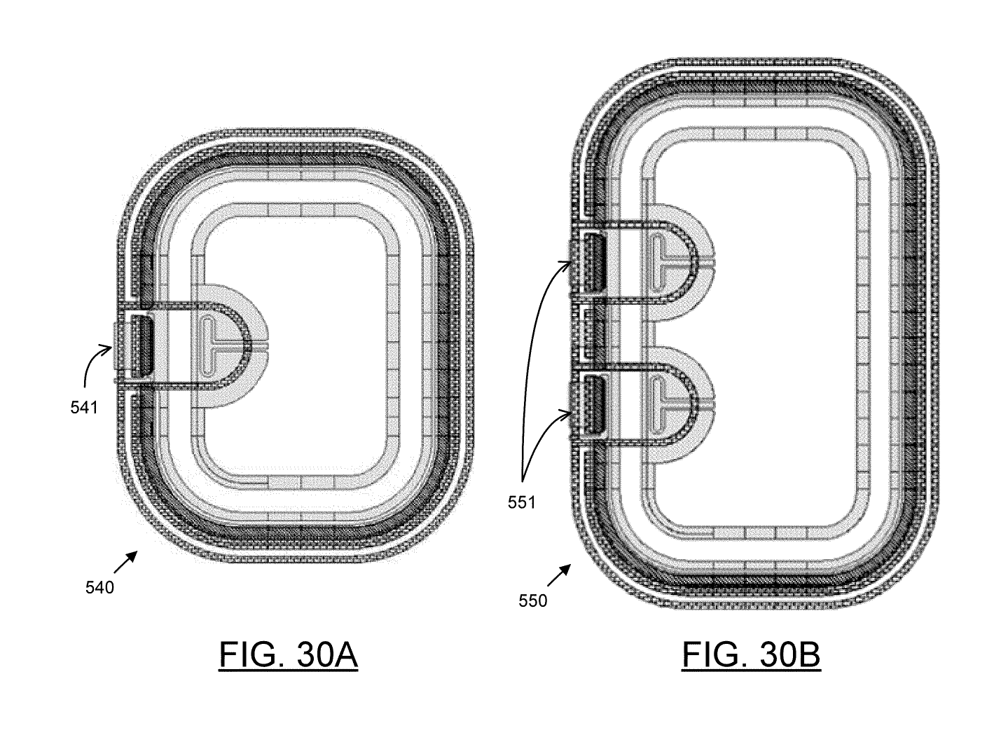

FIG. 30A is a top view illustrating a semiconductor device according to an embodiment of the invention. A semiconductor device 540 of the invention may be configured to have one UHV cell 541 as shown in FIG. 30A. FIG. 30B is a top view illustrating a semiconductor device according to another embodiment of the invention. A semiconductor device 550 of the invention may be configured to have two UHV cells 551 as shown in FIG. 30B. Indeed a semiconductor device of the invention may be configured to have more than two UHV cells.

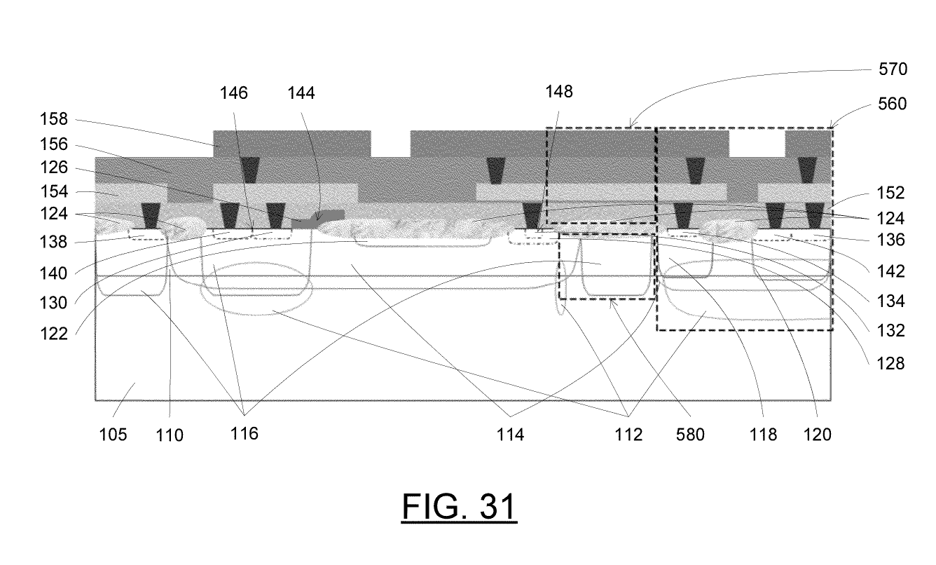

FIG. 31 is a cross-sectional view illustrating an UHV NMOS according to another embodiment of the invention. By way of explanation, the regions of the UHV NMOS of FIG. 31 include a high side operating region (HSOR) 560, a high voltage (HV) interconnection region 570, and a self-shielding region 580. According to an embodiment of the invention, the HV interconnection region 570 is configured to provide the interconnection between the UHV NMOS structure and the HSOR 560. According to certain embodiments of the invention, the self-shielding region 580 isolates the high side (HSOR 560) from the low side (the UHV NMOS structure).

Without intending to be bound by theory, the depth of the HVNW 114 of the HSOR 560, according to certain embodiments of the invention, is such that HV operation may be sustained by the device. Without further intending to be bound by the theory, the implant of the p top layer 122 allows a reduced-surface-field (RESURF) effect to be realized in the device. Without further intending to be bound by the theory, the NBL 112 of the HSOR 560 is configured to prevent punch-through from the HSOR 560 to the substrate or ground. Yet without further intending to be bound by theory, the NBL 112 of the source region 146 may be configured, according to certain embodiments of the invention, to isolate the source and the substrate or the ground.

In certain embodiments of the invention, the HSOR 560 is configured to support at least about 560 V, at least about 600 V, or at least about 650 V. In an embodiment of the invention, the HSOR 560 may be capable of supporting at least about 700 V.

An aspect of the invention provides methods of fabricating semiconductor device of the invention. Any manufacturing process known to those having ordinary skill in the art having the benefit of this disclosure may be used to manufacture the semiconductor devices of the invention.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. An ultra-high voltage metal oxide semiconductor (UHV MOS) device comprising:
a MOS transistor having a doped gradient structure in a drain region;
a high voltage (HV) interconnection region proximate to the MOS transistor, the HV interconnection region having at least one dielectric layer and at least one metal layer;
a self-shielding region proximate to the MOS transistor and aligned with the HV interconnection region; and
a high side operating region (HSOR) separated from the MOS transistor by the HV interconnection region and the self-shielding region.

2. The UHV MOS device of claim 1, wherein the doped gradient structure comprises at least one of a high voltage n- (HVN-) well, a high voltage n-type deep (HVND) well, and an n-type well (NW).

3. The UHV MOS device of claim 1, wherein the doped gradient structure additionally comprises an n+ well.

4. An ultra-high voltage n-type metal oxide semiconductor (UHV NMOS) device comprising:
a substrate having an epitaxial layer disposed in part therein;
a drain region having
an n-doped gradient structure, and
a first n-type buried layer (NBL) at a terminus of the drain region;

5. The UHV NMOS device of claim 4, wherein the epitaxial layer is a p-type epitaxial layer.

6. The UHV NMOS device of claim 4, wherein the n-doped gradient structure comprises at least one of a high voltage n- (HVN-) well, a high voltage n-type deep (HVND) well, and an n-type well (NW).

7. The UHV NMOS device of claim 6, wherein the n-doped gradient structure additionally comprises an n+ well.

8. The UHV NMOS device of claim 4 additionally comprising:
a bulk region and a source region diametrically opposed to the drain region, the bulk region and the source region having
a second NBL disposed in part in the substrate and another part in the epitaxial layer,
a first high voltage p-type deep (HVPD) well disposed in part in the second NBL and a remaining part above the second NBL,
a bulk p+ well disposed in the first HVPD well to define a bulk contact, and
a source n+ well disposed in the first HVPD well to define a source contact,
wherein the second NBL underlies the bulk p+ well and the source n+ well;
a channel region separating the drain region from the bulk region and the source region, the channel region having a first high voltage n well (HVNW) extending from the bulk region and the source region across the channel region to the drain region; and
a gate region proximate to the bulk region and the source region and aligned in part above the channel region, the gate region having a conductive layer.

9. The UHV NMOS device of claim 8, wherein the channel region additionally comprises a p top region disposed along a shielded top surface of the substrate.

10. The UHV NMOS device of claim 9, wherein the p top region comprises a plurality of discrete p top segments.

11. The UHV NMOS device of claim 8 additionally comprising:
a self-shielding region aligned with the terminus of the drain region opposite a side of the drain region aligned with the channel region, the self-shielding region having a second HVPD well;
a high voltage (HV) interconnection region aligned above the self-shielding region having
at least one dielectric layer, and
at least one metal layer; and
a high side operating region (HSOR) separated from the drain region by the HV interconnection region and the self-shielding region having
at least a part of a third NBL that extends across the HSOR,
a second HVNW extending substantially across the HSOR and disposed in part in the third NBL and another remaining part above the third NBL,
an n well (NW) disposed proximate to the self-shielding region,
a p well (PW) disposed diametrically opposed to the NW at an opposite side of the HSOR,
a first HSOR n+ well disposed in the NW,
a HSOR p+ well disposed in the PW, and
a second HSOR n+ well disposed in the PW.

12. The UHV NMOS device of claim 11, wherein the second HVPD well comprises two or more discrete HVPD well segments.

13. The UHV NMOS device of claim 11, wherein:
the at least one dielectric layer comprises an interlayer dielectric (ILD) layer disposed on the substrate and an inter-metal dielectric (IMD) layer, and
the at least one metal layer comprises a first metal disposed on the IDL layer and a second metal layer separated from the first metal layer by the IMD layer.

14. The UHV NMOS device of claim 12, wherein the first metal layer is patterned such that only a portion of the second metal layer is adjacent to and above the self-shielding region.

15. The UHV NMOS device of claim 12, wherein the second metal layer is patterned such that only a portion of the first metal layer is adjacent to and above the self-shielding region.

16. The UHV NMOS device of claim 15, wherein the portion is a patterned region of the first metal layer.

17. The UHV NMOS device of claim 11 additionally comprising:
a substrate contact region aligned with the bulk region and the source region opposite a side of the bulk region and the source region aligned with the channel region, the substrate contact having
a third HVPD well, and
a substrate contact p+ well disposed in the third HVPD well; and
a patterned isolation layer disposed along the substrate.

18. The UHV NMOS device of claim 11 additionally comprising a patterned isolation layer disposed along the substrate.

19. The UHV NMOS device of claim 19, wherein the patterned isolation layer comprises at least one of a field oxide layer and one or more shallow trench isolation (STI) structures.

20. An ultra-high voltage n-type metal oxide semiconductor (UHV NMOS) device comprising:
a substrate having an epitaxial layer disposed in part therein;
a drain region having
an n-doped gradient region, and
a first n-type buried layer (NBL) at a terminus of the drain region;
a bulk region and a source region diametrically opposed to the drain region, the bulk region and the source region having
a second NBL disposed in part in the substrate and another part in the epitaxial layer,
a first high voltage p-type deep (HVPD) well disposed in part in the second NBL and a remaining part above the second NBL,
a bulk p+ well disposed in the first HVPD well to define a bulk contact, and
a source n+ well disposed in the first HVPD well to define a source contact,
wherein the second NBL underlies the bulk p+ well and the source n+ well;
a channel region separating the drain region from the bulk region and the source region, the channel region having
a first high voltage n well (HVNW) extending from the bulk region and the source region across the channel region to the drain region, and
a p top region disposed along a shielded top surface of the substrate;
a gate region proximate to the bulk region and the source region and aligned in part above the channel region, the gate region having a conductive layer;
a self-shielding region aligned with the terminus of the drain region opposite a side of the drain region aligned with the channel region, the self-shielding region having a second HVPD well;
a high voltage (HV) interconnection region aligned above the self-shielding region having
at least one dielectric layer, and
at least one metal layer;
a high side operating region (HSOR) separated from the drain region by the HV interconnection region and the self-shielding region having
at least a part of a third NBL that extends across the HSOR,
a second HVNW extending substantially across the HSOR and disposed in part in the third NBL and another remaining part above the third NBL,
a n well (NW) disposed proximate to the self-shielding region,
a p well (PW) disposed diametrically opposed to the NW at an opposite side of the HSOR,
a first HSOR n+ well disposed in the NW,
a HSOR p+ well disposed in the PW, and
a second HSOR n+ well disposed in the PW;
a substrate contact region aligned with the bulk region and the source region opposite a side of the bulk region and the source region aligned with the channel region, the substrate contact having
a third HVPD well, and
a substrate contact p+ well disposed in the third HVPD well; and
a patterned isolation layer disposed along the substrate.

21. A method of fabricating an ultra-high voltage n-type metal oxide semiconductor (UHV NMOS) device comprising:
providing a substrate;
implanting an n-type buried layer (NBL) in the substrate;
driving in a dopant of the NBL;
depositing an epitaxial layer;
implanting a high voltage p-type deep (HVPD) well;
implanting a high voltage n well (HVNW);
implanting an n well (NW) in the high side operating region (HSOR);
implanting a p well (PW) in the HSOR;
driving in a dopant of the NW;
implanting a p top layer;
forming an isolation layer;
forming a conductive layer; and
implanting an n-doped gradient structure in a drain region.

22. The method of fabricating the UHV NMOS device of claim 21, wherein implanting the n-doped gradient structure in the drain region comprises:
implanting at least one of a high voltage n- (HVN-) well, a drain side high voltage n-type deep (HVND) well, and a drain side n-type well (NW); and
implanting a drain side n+ well in at least one of the HVN- well, the drain side HVND well, and the drain side NW.

23. The method of fabricating the UHV NMOS device of claim 21, additionally comprising:
implanting a source side n+ well, a first HSOR n+ well, and a second HSOR n+ well; and
implanting a substrate contact p+ well, a bulk side p+ well, and a HSOR p+ well.
